(19) United States
(12) Patent Application Publication
(10) Pub. No.: US 2008/0142075 A1
(43) Pub. Date: Jun. 19, 2008

(54) Nanophotovoltaic Device with Improved Quantum Efficiency

(75) Inventors: Damoder Reddy, Los Gatos, CA (US); Boris Gilman, Mountain View, CA (US)

Correspondence Address: MORGAN, LEWIS & BOCKIUS, LLP, ONE MARKET SPEAR STREET TOWER, SAN FRANCISCO, CA, 94105, US

(73) Assignee: Solexant Corporation, San Jose, CA (US)

(21) Appl. No.: 11/951,545

(22) Filed: Dec. 6, 2007

Related U.S. Application Data
(60) Provisional application No. 60/873,139, filed on Dec. 6, 2006.

(51) Int. Cl. H01L 31/0224

(52) U.S. Cl. 136/257

(57) ABSTRACT

Photovoltaic devices or solar cells are provided having one or more photoactive layers where at least one of the photoactive layers comprises a sublayer made of photoactive nanoparticles that differ in size, composition or both.

### RELATED APPLICATION

This patent application claims the benefit of, and priority to, U.S. Provisional Patent Application Ser. No. 60/873,139 filed on Dec. 6, 2006, titled “NanoMaterial Solar Cell with the Enhanced PV Quantum Efficiency,” the disclosure of which is hereby incorporated by reference in its entirety.

### FIELD OF THE INVENTION

In general, the present invention relates to the field of photovoltaics or solar cells. More particularly, the present invention relates to photovoltaic devices having photoactive layers made of sublayers of photoactive nanoparticles.

### BACKGROUND OF THE INVENTION

Increasing oil prices have heightened the importance of developing cost effective renewable energy. Significant efforts are underway around the world to develop cost effective solar cells to harvest solar energy. Current solar energy technologies can be broadly categorized as crystalline silicon and thin film technologies. More than 90% of the solar cells are made from silicon—single crystal silicon, polycrystalline silicon or amorphous silicon.

Historically, crystalline silicon (c-Si) has been used as the light-absorbing semiconductor in most solar cells, even though it is a relatively poor absorber of light and requires a considerable thickness (several hundred microns) of material. Nevertheless, it has proved convenient because it yields stable solar cells with good efficiencies (12-20%, half to two-thirds of the theoretical maximum) and uses process technology developed from the knowledge base of the microelectronics industry.

Two types of crystalline silicon are used in the industry. The first is monocrystalline, produced by slicing wafers (approximately 150 mm diameter and 350 microns thick) from a high-purity single crystal boule. The second is multicrystalline silicon, made by sawing a cast block of silicon first into bars and then wafers. The main trend in crystalline silicon cell manufacture is toward multicrystalline technology. For both mono- and multicrystalline Si, a semiconductor p-n junction is formed by diffusing phosphorus (an n-type dopant) into the top surface of the boron doped (p-type) Si wafer. Screen-printed contacts are applied to the front and rear of the cell, with the front contact pattern specially designed to allow maximum light exposure of the Si material with minimum electrical (resistive) losses in the cell.

Silicon solar cells are very expensive. Manufacturing is mature and not amenable for significant cost reduction. Silicon is not an ideal material for use in solar cells as it primarily absorbs in the visible region of the solar spectrum thereby limiting the conversion efficiency.

Second generation solar cell technology is based on thin films. Two main thin film technologies are amorphous silicon and CIGS.

Amorphous silicon (a-Si) was viewed as the “only” thin film PV material in the 1980s. But by the end of that decade, and in the early 1990s, it was dismissed by many observers for its low efficiencies and instability. However, amorphous silicon technology has made good progress toward developing a very sophisticated solution to these problems: multijunction configurations. Now, commercial, multijunction a-Si modules could be in the 7%-9% efficiency range. United Solar Systems Corporation and Kanaka plan have built 25-MW manufacturing facilities and several companies have announced plans to build manufacturing plants in Japan and Germany. United Solar plans to build 100 MW facilities in the near future.

The key obstacles to a-Si technology are low efficiencies (about 11% stable), light-induced efficiency degradation (which requires more complicated cell designs such as multiple junctions), and process costs (fabrication methods are vacuum-based and fairly slow). All of these issues are important to the potential of manufacturing cost-effective a-Si modules.

Thin film solar cells made from Copper Indium Gallium Diselenide (CIGS) absorbers show promise in achieving high conversion efficiencies of 10-12%. The record high efficiency of CIGS solar cells (19.5% NREL) is by far the highest compared with those achieved by other thin film technologies such as Cadmium Telluride (CdTe) or amorphous Silicon (a-Si).

These record breaking small area devices have been fabricated using vacuum evaporation techniques which are capital intensive and quite costly. It is very challenging to fabricate CIGS films of uniform composition on large area substrates. This limitation also affects the process yield, which are generally quite low. Because of these limitations, implementation of evaporation techniques has not been successful for large-scale, low-cost commercial production of thin film solar cells and modules and is non-competitive with today's crystalline silicon solar modules.

To overcome the limitations of the physical vapor deposition techniques that use expensive vacuum equipment, several companies have been developing high throughput vacuum processes (ex: DayStar, Global Solar) and non-vacuum processes (ex: ISET, Nanosolar) for the fabrication of CIGS solar cells. Using ink technology, very high active materials utilization can be achieved with relatively low capital equipment costs. The combined effect is a low-cost manufacturing process for thin film solar devices. CIGS can be made on flexible substrates making it possible to reduce the weight of solar cells. Cost of CIGS solar cells is expected to be lower than crystalline silicon making them competitive even at lower efficiencies. Two main problems with CIGS solar cells are: (1) there is no clear pathway to higher efficiency and (2) high processing temperatures make it difficult to use high speed roll to roll process and hence they will not be able to achieve significantly lower cost structure.

These are significant problems with the currently available technologies. Crystalline silicon solar cells which have >90% market share today are very expensive. Solar energy with c-silicon solar cells costs about 25 cents per kwh as compared to less than 10 cents per kwh for fossil fuels. In addition, the capital cost of installing solar panels is extremely high limiting its adoption rate. Crystalline solar cell technology is mature and unlikely to improve performance or cost competitiveness in near future. Amorphous silicon thin film technology is amenable to high volume manufacturing that could lead to low cost solar cells. In addition, amorphous and microcrystal silicon solar cells absorb only in the visible region.

Next generation solar cells are required to truly achieve high efficiencies with light weight and low cost. Two potential candidates are (1) polymer solar cells and (2) nanoparticle solar cells. Polymer solar cells have the potential to be low cost due to roll to roll processing at moderate temperatures (<150 C). However, polymers suffer from two main drawbacks: (1) poor efficiencies due to slow charge transport and (2) poor stability—especially to UV radiation. Hence it is unlikely that polymer solar cells will be able to achieve the required performance to become the next generation solar cell. The most promising technology for the next generation solar cell is based on quantum dot nanoparticles.

Several research groups have been conducting experimental studies on quantum dot based solar cells. Most commonly used quantum dots are made of compound semiconductors such as Group II-VI, II-IV and III-V. Some examples of these photosensitive quantum dots are CdSe, CdTe, PbSe, PbS, ZnSe.

Solar cells made from photosensitive nanoparticles as described in the art show very low efficiencies (<5%). Nanoparticles are very efficient in generating electron hole charge pairs when exposed to sunlight. The primary reason for these low efficiencies is charge recombination. To achieve high efficiencies in a solar cell the charges must be separated as soon as possible after they are generated. Charges that recombine do not produce any photocurrent and hence do not contribute towards solar cell efficiency. Charge recombination in nanoparticles is primarily due to two factors: (1) surface states on nanoparticle that facilitate charge recombination, and (2) slow charge transport. In the later case, charge recombination is generally faster compared to the charge transport rate because charges travel slowly through the electron transport and hole transport layers.

### SUMMARY OF THE INVENTION

In one embodiment, the photovoltaic device comprises first and second electrodes, at least one of which is a transparent electrode that is substantially transparent to all or part of the solar spectrum. A photoactive layer is disposed between the first and second electrodes. The photoactive layer comprises a first sublayer comprising first photoactive nanoparticles having a first band gap and a second sublayer comprising second photoactive nanoparticles having a second bandgap. The second bandgap is smaller than the first bandgap. The first sublayer is preferably disposed closer to the transparent electrode than said second sublayer.

The first photoactive nanoparticles in the first and second sublayers can be the same except that nanoparticles in the first sublayer have a different size as compared to the size of said second photoactive nanoparticles in the second sublayer.

Alternatively the first and the second photoactive nanoparticles are ternary compositions that differ from each other in the amount of at least one atomic element that is present in the first and second photoactive nanoparticles.

The photoactive nanoparticles in each case are chosen to produce the first and the second bandgaps within the first photoactive layer.

In yet another embodiment, at least one of the first or second sublayers comprises a mixture of (i) photoactive nanoparticles of the same size and (ii) photoactive nanoparticles having different composition. The nanoparticles in the mixture are chosen so that they have substantially the same band gap.

In other embodiments, the photovoltaic device further includes a hole conducting layer positioned between one of the electrodes and the photoactive layer to facilitate hole transfer to that electrode.

In the same or other embodiments, an electron conducting layer is positioned between the other electrode and the photoactive layer to facilitate electron transfer to that electrode.

Electron blocking and hole blocking layers can also be used in association with the appropriate electrodes.

The photovoltaic device can also have a second photoactive layer. The second photoactive layer can be chosen from any of the photoactive layers that are known in the art such as doped silicon (crystalline or amorphous), thin film semiconductors (e.g. CIGS) and organic polymers containing dyes or photoactive nanoparticles. The second photoactive layer, however, can also comprise a first sublayer comprising first photoactive nanoparticles having a first band gap and a second sublayer comprising second photoactive nanoparticles having a second bandgap which is smaller than the first bandgap. The first sublayer in the second photoactive layer is preferably disposed closer to the transparent electrode than the second sublayer in the second photoactive layer. The first and second band gaps in the second photoactive layer are different from the first and second bandgaps of the first photoactive layer. When a second photoactive layer is used it is preferred that a recombination layer be positioned between the two photoactive layers.

The photovoltaic device can also include a third photoactive layer. The third photoactive layer can be chosen from any of the photoactive layers known in the art. Alternatively, the third photoactive layer can comprise a first sublayer comprising first photoactive nanoparticles having a first band gap and a second sublayer comprising second photoactive nanoparticles having a second bandgap which is smaller than the first bandgap. The first sublayer is disposed closer to the transparent electrode than the second sublayer. In addition, the first and second band gaps in the third photoactive layer are different from the first and second bandgaps of the first and the second photoactive layers.

In one embodiment, the first photoactive layer adsorbs UV, visible or infrared solar radiation. If a second photoactive layer is used, it is preferred that the first photoactive layer adsorb UV, visible or infrared solar radiation and the second photoactive layer adsorb one of the other of UV, visible or infrared solar radiation.

When a third photoactive layer is present it is preferred that the first, second and third photoactive layers each adsorb one of UV, visible or infrared solar radiation.

A distinguishing characteristic of the photovoltaic device is a photoactive layer containing a multiplicity of sublayers that are each defined by photosensitive nanoparticles that have different bandgaps. The nanoparticles in the different sublayers are chosen so that they have a Type II bandgap alignment. These bandgaps also define the region of the solar spectrum which the photoactive layer adsorbs. In a standard photovoltaic device, each photoactive layer contains one type of nanoparticle with a defined size range. Such particles are chosen to exploit their adsorption in the UV, visible or IR regions of the spectrum. For example, PbS or InP nanoparticles can be used in a photoactive layer to adsorb IR radiation. However, an IR adsorbing photoactive layer herein contains at least two sublayers with, for example, PbS or InP nanoparticles having different sizes.

### BRIEF DESCRIPTION OF THE FIGURES

The foregoing and other aspects of the present invention will be apparent upon consideration of the following detailed description, taken in conjunction with the accompanying drawings, in which like reference characters refer to like parts throughout, and in which:

FIG. 4 is a schematic representation of Core-Shell quantum dots (Examples: PbSe, PbS and InP);

FIG. 5 illustrates Quantum dots (quantum dot) of different size absorb and emit at different colors according to embodiments of the present invention;

FIG. 6 illustrates nanoparticles capped with solvents such as tr-n-octyl phosphine oxide (TOPO);

FIG. 7 shows functionalized nanoparticles prepared according to embodiments of the present invention;

FIG. 8 is a schematic drawing showing one embodiment of a photovoltaic device of the present invention with a first photoactive layer comprising two or more sublayers (not shown) of IR absorbing nanoparticle integrated with a second photoactive layer made of amorphous or microcrystalline silicon layers;

FIG. 9 is a schematic diagram illustrating one embodiment of a recombination layer;

FIG. 10 illustrates a schematic drawing showing another embodiment of a photovoltaic device with a first photoactive layer comprising two or more sublayers (not shown) of IR adsorbing nanoparticles integrated with a second photoactive layer made of polycrystalline or single crystal silicon layers;

FIG. 11 shows a photovoltaic device having a first photoactive layer comprising two or more sublayers (not shown) of IR harvesting nanoparticles integrated with a second photoactive layer made of CdTe;

FIG. 12 depicts a photovoltaic device with a first photoactive layer comprising two or more sublayers (not shown) of IR harvesting nanoparticles integrated with a second photoactive layer made of CIGS;

FIG. 13 shows a schematic drawing showing one embodiment of a photovoltaic device having a first photoactive layer comprising two or more sublayers (not shown) of UV absorbing or harvesting nanoparticle layers integrated with a second photoactive layer made of amorphous or microcrystalline silicon layers;

FIG. 14 is a schematic drawing showing one embodiment of a photovoltaic device having a first photoactive layer comprising two or more sublayers (not shown) of UV harvesting nanoparticle layers integrated with a second photoactive layer made of polycrystalline silicon or single crystal silicon layers;

FIG. 15 depicts a schematic drawing showing one embodiment of a photovoltaic device having a first photoactive layer comprising two or more sublayers (not shown) of UV harvesting nanoparticle layers integrated with a second photoactive layer made of CdTe layers;

FIG. 16 illustrates a schematic drawing showing one embodiment of a photovoltaic device having a first photoactive layer comprising two or more sublayers (not shown) of UV harvesting nanoparticle layers integrated with a second photoactive layer made of CIGS layers;

FIG. 17 shows a photovoltaic device with UV & IR absorbing photoactive layers each made of two sublayers of different nanoparticles (not shown) integrated with an amorphous or microcrystalline silicon visible adsorbing photoactive layer.

FIG. 18 illustrates a photovoltaic device with UV & IR photoactive layers each made of two sublayers of different nanoparticles (not shown) integrated with a polycrystalline or single crystal silicon visible adsorbing photoactive layer;

FIG. 19 shows UV & IR photoactive layers each made of two sublayers of different nanoparticles (not shown) integrated with CdTe;

FIG. 20 shows UV & IR photoactive layers each made of two sublayers of different nanoparticles (not shown) integrated with a CIGS photoactive layer;

FIG. 21 illustrates another embodiment of a photovoltaic device having a UV photoactive layer made of at least two sublayers of different UV adsorbing nanoparticles integrated with III-V semiconductor photoactive layers;

FIG. 22 illustrates a four junction crystalline silicon solar cell integrated with an IR photoactive layer made of at least two sublayers of different IR adsorbing nanoparticles;

FIG. 23 shows a four junction crystalline silicon solar cell integrated with a UV adsorbing photoactive layer made of at least two sublayers (not shown) of different UV adsorbing nanoparticles;

FIG. 24 shows a four junction thin film solar cell integrated with an IR adsorbing photoactive layer made of at least two sublayers (not shown) of different IR adsorbing nanoparticles;

FIG. 25 depicts a four junction thin film solar cell integrated with UV adsorbing photoactive layer made of at least two sublayers (not shown) of different UV adsorbing nanoparticles;

FIG. 26 shows a schematic drawing of a nanocomposite photovoltaic device with a photoactive layer made of two or more sublayers (not shown) of different photosensitive nanoparticles dispersed in a polymer precursor;

FIG. 27 shows a schematic drawing of a nanocomposite photovoltaic device with a photoactive layer made of two or more sublayers (not shown) of a mixture of polymer and polymer precursor;

FIG. 28 depicts a schematic drawing of a nanocomposite photovoltaic device with a photoactive layer having at least two sublayers made of different photosensitive nanoparticles attached to carbon nanotubes (SWCNT) dispersed in a polymer precursor;

FIG. 29 illustrates a nanocomposite photovoltaic device with a photoactive layer having at least two sublayers of different photosensitive nanoparticles attached to carbon nanotubes (SWCNT) dispersed in a mixture of polymer and polymer precursor;

FIG. 30 shows a nanocomposite photovoltaic device and conducting nanostructures such as SWCNT dispersed in a mixture of polymer and polymer precursor;

FIG. 31 shows a nanocomposite photovoltaic device having a photoactive layer having at least two sublayers made of different photosensitive nanoparticles and conducting nanostructures such as SWCNT dispersed in a mixture of polymer and polymer precursor; and

### DETAILED DESCRIPTION OF THE INVENTION

Embodiments of the present invention generally relate to the field of photovoltaic or solar cells. More particularly, the present invention provides photovoltaic devices having one or more photoactive layers at least one of which comprises two or more sublayers of photoactive (also sometimes referred to as photosensitive) nanoparticles having different bandgaps. The use of such photoactive layers results in an increase in the quantum efficiency (QE) of the photoactive layer which is a component of the power conversion efficiency (PCE) of the photovoltaic device.

As used here a “photoactive layer” refers to a layer within a photovoltaic device that is characterized, in part, by the wavelength/frequency of the solar radiation that it absorbs. This absorption, in turn, is based on the bandgap(s) of the material(s) present in the photoactive layer. Many types of photoactive layers are known in the art, including well-known semiconducting materials based on crystalline and amorphous silicon, various thin-film technologies that utilize amorphous silicon and semiconductors and organic polymers that contain photoactive dyes. the other photoactive layers can also be made, in part or in whole, with photoactive nanoparticles.

As used herein, the term “sublayers” refers to a multiplicity of layers of nanoparticles that are in charge transfer communication with each other. The sublayers are components of a photoactive layer. In general, there are at least two, sometimes three and in some cases more sublayers up to about 5, 7 or 10 in a given photoactive layer. The sublayers in any given photoactive layer are related to each other by being made of nanoparticles that are either (1) of the same composition but of a different particle size, (2) the same size but have different composition, including but not limited to ternary compositions made of three or more elements wherein the amount of one or more atomic elements in the composition changes between sublayers or (3) a mixture of both (provided the bandgaps and energy levels are closely related. Each sublayer is preferably less than 200 nm thick, more preferably less than 100 nm thick still more preferably less than 75 nm or 50 nm thick. The sublayer may be as thin as a single monolayer of nanoparticles and therefore defined by the dimension of the nanoparticle, although the thickness may be as small as two, three, four, five, six, seven, eight nine or ten nanoparticle monolayers. The upper limit of any of the foregoing is any of the preferred upper limits set forth above.

If a nanoparticle population has a relatively broad size distribution it will have a relatively broad adsorption peak. If the particles are size separated into two populations each population would have unique adsorption peaks. If used in separate sublayers, the overall adsorption of the “photoactive layer” will be the same, or approximately the same, as the original population. The advantage in ordering the particles in separate layers is to provide additional driving force to bring about charge separation across the sub-layers which will increase the solar cell efficiency.

The Type II orientation and difference in bandgaps creates a potential gradient across the photoactive layer containing the nanoparticles sublayers. This gradient increases the driving force for the transport of charge carriers across the photoactive layer thereby enhancing the quantum efficiency. This results in a significant additional chemical potential gradient developed across the photoactive layer in a direction orthogonal to the electrodes. This gradient is essentially equivalent to the enhancing of the electric field produced by the metal work function difference between the contact metals (electrodes of the photovoltaic device). The gain in quantum efficiency may be as high as 50-150% (1.5-2.5×).

When the nanoparticles are of the same composition, the nanoparticle size variation (or bandgap variation) within a sublayer is preferably smaller than the average size difference between the two adjacent sublayers. For example in a photoactive layer having three sublayers of 50 nm thickness each, the difference in particle size between the layers can be very small such as 4 nm particles in the first sublayer, 5 nm particles in the second sublayer and 6 nm particles in the third sublayer. In this situation it is preferred that the variation in size of the nanoparticles in each layer be no more that about +/−10%. Lower variations are also possible but there are practical limitations when working with particles of this size. Such structures would provide a fairly smooth and monotonous band gap variation across the thickness of the photoactive layer. The actual layer thickness can be varied depending on the absorption requirements in the wavelength targeted for that layer.

In other embodiments, the size distribution is a step function between sublayers. For a photoactive layer with three sublayers of 50 nm thickness each, the particle size can be 6 nm +/−10% in the first sublayer, 8 nm +/−10% in the second sublayer and 8 nm +/−10% in the third sublayer. Such a structure would be expected to produce a small but distinct band gap at the interface of the of the sublayers within a given photoactive layer.

FIG. 1 depicts the prior art photovoltaic device with nanoparticles of a specified size range in a single layer. By way of contrast, FIG. 2 shows the same quantum dots in a photoactive layer arranged in the size of increasing order in such a way that the smallest quantum dots are located closer to the hole conducting layer while the largest quantum dots are located at the Back Metal region. The respective sub-layer thickness and the number of sub-layers depend on the total photoactive layer thickness and the number of nanoparticles grades. For instance, for a 150 nm thick photoactive layer and nanoparticle size varying from 3 to 9 nm the approximate sub-layer thickness will be in the 15-25 nm range. The approximate light absorption trend is also shown in FIG. 3. Apparently due to the different energy quantization in quantum dots of different size the longer wavelength absorption is expected to shift toward the far end of the photoactive layer thus providing a smoother absorption profile in the film. As shown in the lower portion of FIG. 3, the corresponding energy level split facilitates quantum dot-assisted electron transport (hopping) toward the Back Metal thus enhancing the drift velocity and related quantum efficiency of the nanocomposite solar cell. In case of hole-conductive quantum dots the similar enhancement is expected for the hole transport (not shown in the figure).

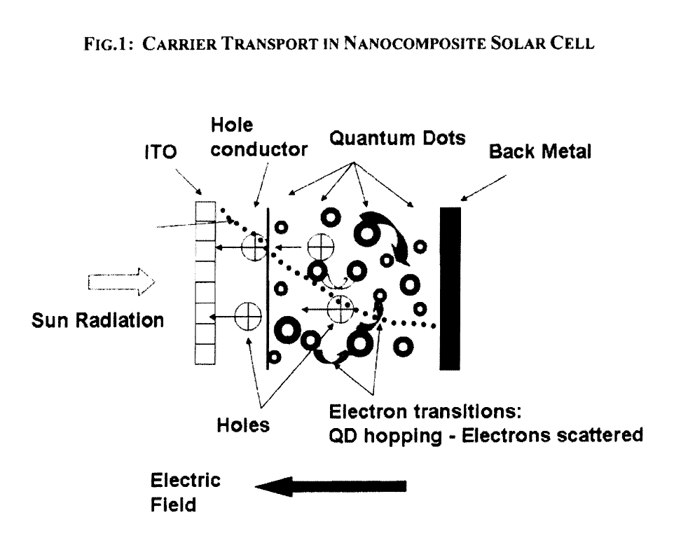

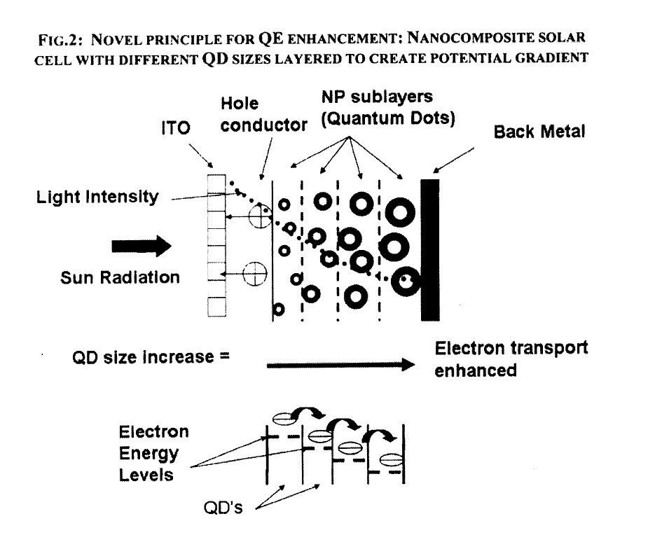

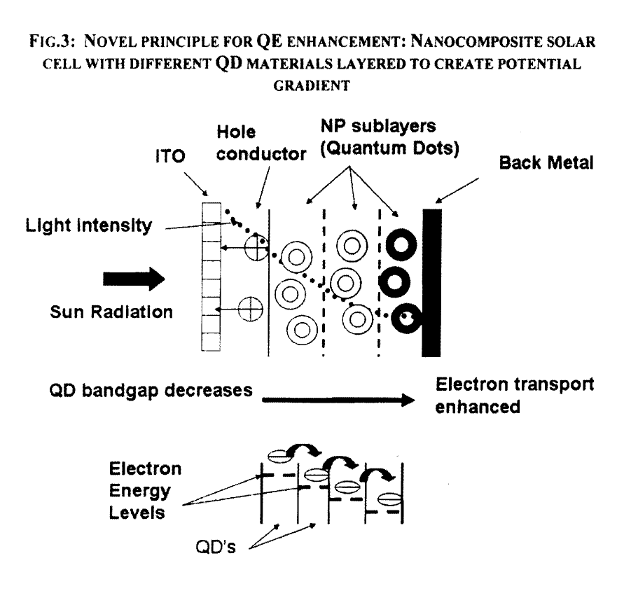

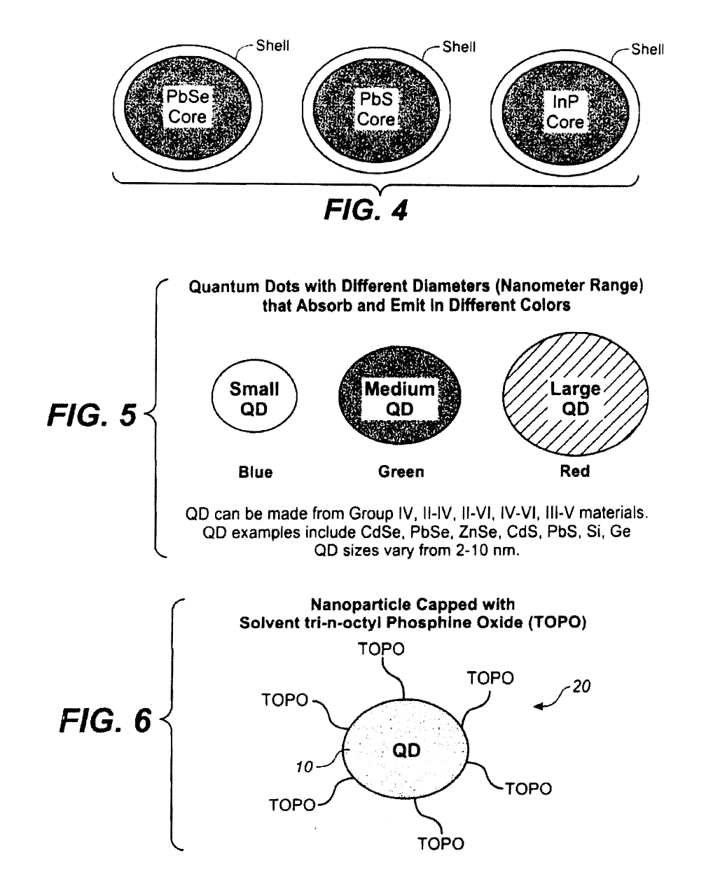

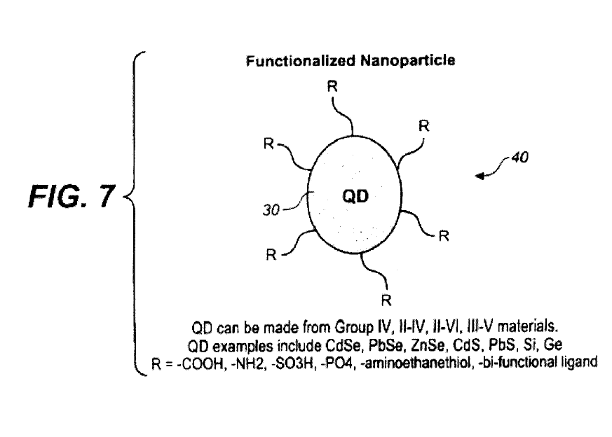

In the embodiment shown in FIG. 4 the quantum dots of same size but different materials in the nanocomposite film are arranged in such a way that the quantum dots with largest bandgap are located closer to the Hole conducting layer while the quantum dots with smallest bandgap are located at the Back Metal region. The respective sub-layer thickness and the number of sub-layers depend on the total film thickness and the number of quantum dot material grades. For instance for the 150 nm thick photoactive layer with different types of quantum dot materials, the approximate sub-layer thickness will be in the 25-30 nm range. The approximate light absorption trend is also shown in FIG. 4. Apparently due to the different energy quantization in quantum dots of different size the longer wavelength absorption is expected to shift toward the far end of the nanocomposite film thus providing a smoother absorption profile in the film. As shown in the lower portion of FIG. 4, corresponding energy level split facilitates quantum dot-assisted electron transport (hopping) toward the Back Metal thus enhancing the drift velocity and related QE of the NC cell. In case of hole-conductive quantum dots the similar enhancement is expected for the hole transport (not shown).

The photoactive layer thickness can vary from 50 nm to 5,000 nm. The sublayer thickness can range from the thickness of a single nanoparticle layer (e.g., 2 nm, 3 nm, 5 nm, etc. depending on the size of the quantum dots) to approximately half the thickness of the layer. For example if photoactive layer thickness is 500 nm it could comprise five different sublayers with each sublayer being 100 nm thick although the sublayers do not need to be of equal thickness. Within each sublayer nanoparticles will have substantially the same dimension.

As used herein, the term “nanoparticle” or “photoactive nanoparticle” refers to photosensitive materials that generate electron hole pairs when exposed to solar radiation. Photosensitive nanoparticles are generally nanocrystals such as quantum dots, nanorods, nanobipods, nanotripods, nanomultipods, or nanowires.

Photoactive nanoparticles can be made from compound semiconductors which include Group II-VI, II-IV and III-V materials. Some examples of photoactive nanoparticles are CdSe, ZnSe, PbSe, InP, PbS, ZnS, CdTe Si, Ge, SiGe, CdTe, CdHgTe, and Group II-VI, II-IV and III-V materials. Alternatively, the nanoparticles can be a ternary composition made up of 3 or more elements such as CdHgTe, CuInSe, CuInGSe. Photoactive nanoparticles can be core type or core-shell type. In a core shell nanoparticle, the core and shell are made from different materials. Both core and shell can be made from compound semiconductors.

Quantum dots are a preferred nanoparticle. As in known in the art, quantum dots having the same composition but having different diameters absorb and emit radiation at different wave lengths. FIG. 1 depicts three quantum dots made of the same composition but having different diameters. The small quantum dot absorbs and emits in the blue portion of the spectrum; whereas, the medium and large quantum dots absorb and emit in the green and red portions of the visible spectrum, respectively. Alternatively, as shown in FIG. 2, the quantum dots can be essentially the same size but made from different materials. For example, a UV-absorbing quantum dot can be made from zinc selenide; whereas, visible and IR quantum dots can be made from cadmium selenide and lead selenide, respectively. Nanoparticles having different size and/or composition can be used in any of the photoactive layers to produce a broadband solar cell that absorbs in the UV, visible, and/or IR.

In some embodiments, the photoactive nanoparticle is modified to contain a linker Xₐ—Rₙ—Y_{b} where X and Y can be reactive moieties such as carboxylic acid groups, phosphonic acid groups, sulfonic acid groups, amine containing groups etc., a and b are independently 0 or 1 where at least one of a and b is 1, R is a carbon, nitrogen, sulfur and/or oxygen containing group such as —CH₂, —NH—, —S— and/or —O—, and n is 0-10. One reactive moiety can react with the nanoparticle while the other can react with a negative moiety on another nanoparticle or with an organic polymer if used to form the sublayer. The linkers also passivate the nanoparticles and increase their stability, light absorption and photoluminescence. They can also improve the nanoparticle solubility or suspension in common organic solvents.

Functionalized nanoparticles can also be sensitized by linkage to nanostructures such as SWCNT, other nanotubes or nanowires. By adjusting the components of Xₐ—Rₙ—Y_{b}, the distance between the surface of (1) the nanostructure and nanoparticle can be adjusted to minimize the effect of surface states in facilitating charge recombination. The distance between these surfaces is typically 10 Angstroms or less preferably 5 angstroms or less. This distance is maintained so that electrons tunnel through this gap from the nanoparticles to the highly conducting nanostructures. This facile electron transport helps in reducing charge recombination and results in efficient charge separation which leads to efficient solar energy conversion.

In some embodiments the photoactive layer is an electron conducting or a hole conducting layer and the photovoltaic device further comprises an electron or hole conducting layer which is other than said electron or hole conducting photoactive layer. These layers are in electron or hole conducting communication with the photoactive layer.

In some embodiments first and second sublayers comprise nanoparticles having the same composition. The nanoparticles of said first sublayer have a different size as compared to the size of the nanoparticles in the second sublayer and the photovoltaic device further comprises a second photoactive layer. The photovoltaic device can also include a recombination layer disposed between said first and said second photoactive layers.

In some embodiments, when one of the sublayers of the photoactive layer further comprises an organic polymer, at least one of the other sublayers does not contain an organic polymer or the photovoltaic device further comprises a second photoactive layer.

In some embodiments of the photovoltaic device, the sublayers of said photoactive layer are not in direct charge conducting communication with the electrode(s) via a nanostructure, i.e., nanoparticle-nanostructure-electrode.

As used herein a “hole conducting layer” is a layer that preferentially conducts holes. Hole transporting layers can be made from (1) inorganic molecules including p-doped semiconducting materials such as p-type amorphous or microcrystalline silicon or germanium; (2) organic molecules such as metal-thalocyanines, aryl amines etc.; (3) conducting polymers such as polyethylenethioxythiophene (PEDOT), P3HT, P30T and MEH-PPV; and (4) p-type CNTs or p-type SWCNTs.

As used herein an “electron conducting layer” is a layer that preferentially conducts electrons. Electron transporting layers can be made from aluminum quinolate (AIQ₃) and/or n-type CNTs or n-type SWCNTs.

In some embodiments, the solar cell is a broadband solar cell that is capable of absorbing solar radiation at different wave lengths. Photosensitive nanoparticles generate electron-hole pairs when exposed to light of a specific wave length. The band gap of the photosensitive nanoparticles can be adjusted by varying the particle size or the composition of the nanoparticles. By combining a range of nanoparticle sizes and a range of the nanomaterials used to make the nanoparticles, broadband absorption over portions of or the entire solar spectrum can be achieved.

In some embodiments, the photoactive layer or sublayers are is comprised of a polymer composite obtained by dispersing nanoparticles in a conducting polymer matrix. In some cases, the nanoparticles have a core-shell configuration. In this situation, the core of the core-shell can comprise semiconductor materials, such as III-V, II-IV semiconductors, and the like. The shell may be comprised of another semiconductor material or a solvent, for example TOPO. In some embodiments nanoparticles are functionalized, such as with an organic group to facilitate their dispersion in conducting polymer matrix. Such nanoparticles comprise Group IV, II-IV, III-V, II-VI, IV-VI materials. Alternatively, the nanoparticles are comprised of any one or more of CdSe, PbSe, ZnSe, CdS, PbS, Si, SiGe or Ge. In some example the nanoparticles are functionalized with functional groups such as carboxylic (—COOH), amine (—NH2), phosphonate (—PO4), Sulfonate (—HSO3), Aminoethanethiol, and the like.

Nanoparticle-based photoactive layers and sublayers can be deposited by known solution processing methods such as spin coating, dip coating, ink-jet printing, and the like. Nanoparticles can also be deposited by vacuum deposition techniques, where applicable. Thickness, particle sizes, photoactive materials type, type of polymer materials (if used) and the nanoparticle loading level in the polymer composite (if polymer composite is used) can be adjusted to maximize absorption in the IR region for IR absorbing nanoparticles in the visible region for visible absorbing nanoparticles in the UV region for the UV absorbing nanoparticles.

In other embodiments, the photoactive layer and/or sublayers are comprised of a mixture of photoactive nanoparticles and conductive nanoparticles. One or both of the photoactive and conductive nanoparticles may be functionalized. Examples of conductive nanoparticles include, but are not limited to, any one or more of: single wall carbon nanotubes (SWCNT), TiO₂ nanotubes, or ZnO nanowires. Examples of photoactive nanoparticles include, but are not limited to, any one or more of: CdSe, ZnSe, PbSe, InP, Si, Ge, SiGe, or Group III-V materials.

Examples of high mobility conducting polymers include but are not limited to: Pentacene, P3HT, PEDOT, and the like. Precursors for these polymers may contain one or more thermally polymerizable functional groups. Epoxy is an example a suitable thermally polymerizable functional group. Alternately the precursors may contain one or more UV polymerizable functional group. Acrylic functional group is an example of a suitable UV polymerizable functional group.

In some embodiments, a second conducting polymer material is combined with the precursor of high mobility polymer and photosensitive nanoparticles to aid in the initial film formation before the precursor is polymerized. PVK is an example of a suitable secondary polymeric material. It is preferred that the precursor and secondary polymer be mixed at a maximum ratio of precursor to secondary polymer, as long as the phase separation does not occur after polymerization. In one embodiment pentacene is precursor that is expected to plasticize the PVK film allowing uniform dispersion of photosensitive nanoparticles in the film and also allowing conformal coating of nanoparticles with the precursor.

In some embodiments, the photoactive layer or sublayer is comprised of a mixture of photosensitive and conductive nanoparticles. Conductive nanoparticles such as carbon nanotubes, TiO2 nanotubes, ZnO nanowires can be mixed with the precursor and photosensitive nanoparticles (optionally with the second conducting polymer) to further enhance charge separation of electrons and holes generated by the nanoparticles upon their exposure to light. In other embodiments, the photoactive layer or sublayers are comprised of a mixture of photoactive nanoparticles and conductive nanoparticles.

Photosensitive nanoparticles can be chemically attached to the conducting nanostructures based on carbon nanotubes via molecular self assembly so as to form mono layers of these nano particles on the carbon nanotubes. Conducting carbon nanotubes are prepared by methods known in the art. In some embodiments, carbon nanotubes are preferably comprised of single wall carbon nanotubes (SWCNT). The carbon nanotubes can be functionalized to facilitate their dispersion in suitable solvents. Functionalized nanoparticles are reacted with a suitable functional groups (ex: carboxylic or others) on carbon nanotubes to deposit a monolayer of dense continuous nanoparticles by molecular self assembly process. By adjusting the functional group on the nanoparticles and the carbon nanotubes, the distance between the surface of the nanostructure and nanoparticle can be adjusted to minimize the effect of surface states in facilitating charge recombination. This distance is maintained such that electrons tunnel through this gap from the nanoparticles to the highly conducting nanostructures. In some embodiments this distance is a few angstroms, preferably less than 5 angstroms. This facile electron transport will eliminate charge recombination and result in efficient charge separation which will lead to efficient solar energy conversion. In one embodiment, photosensitive nanoparticles are attached to the carbon nanotubes by reacting them in a suitable solvent. Conducting carbon nanotubes may be grown directly on a substrate (ex: metal foil, glass coated with conducting oxide such as ITO) by following methods known in the art. Photosensitive nanoparticles can be attached to the carbon nanotubes grown on the substrate.

In some embodiments, the first photoactive layer exhibits a bandgap of 2 eV and greater, the third photoactive layer exhibits a bandgap of 1.2 eV and lower, and the second photoactive layer exhibits a bandgap between that of the first and third photoactive layers.

In some embodiments, when two or more photoactive layers are used it is preferred that a recombination layer be disposed between the photoactive layers. The recombination layer may be comprised of a doped layer comprised of a material that conducts charge opposite that of the photoactive layer. Thus in some embodiments, the recombination layer will include a doped layer with a charge opposite that of a conducting polymer in the photoactive layer. Alternatively, the recombination layer is a doped layer comprised of a material that conducts charge opposite that of the nanoparticles in the photoactive layer. The recombination layer may further comprise a metal layer and/or an insulator layer coupled to a doped layer.

### EXAMPLES

### Example 1

### Preparation

In the embodiment shown in FIG. 4 the photoactive layer is a nanocomposite film with three sublayers of quantum dots and a hole conducting sublayer. The quantum dots in each of the sublayers have essentially the same size but have different compositions. The sublayers are arranged in such a way that the quantum dots with the largest bandgap are located closer to the first electrode while the quantum dots with smallest bandgap are located closer to the second electrode (the Back Metal region). The respective sub-layer thickness and the number of sub-layers depend on the total film thickness and the number of quantum dot material grades. For instance for the 150 nm thick nanocomposite film with different types of quantum dot materials, the approximate sub-layer thickness will be in the 25-30 nm range. The approximate light absorption trend is also shown in FIG. 4. Due to the different energy quantization in quantum dots of different size the longer wavelength absorption is expected to shift toward the far end of the nanocomposite film thus providing a smoother absorption profile in the film. As shown in the lower portion of FIG. 4, corresponding energy level split facilitates quantum dot-assisted electron transport (hopping) toward the Back Metal thus enhancing the drift velocity and related quantum efficiency of the nanocomposite cell. In case of hole-conductive quantum dots a similar enhancement is expected for the hole transport (not shown).

### Example 2

In the embodiment shown in FIG. 3 the quantum dots in the nanocomposite film (photoactive layer) are made up of three elements, and the quantum dots are arranged such that the smallest quantum dots are located closer to the first electrode while the biggest quantum dots are located closer to the second electrode (the Back Metal region). The bandgap of the quantum dots also varies inversely with size (the smallest quantum dot has the largest bandgap). The respective sub-layer thickness and the number of sub-layers depend on the total nanocomposite film thickness and the number of types of quantum dots. For instance for the 150 nm thick nanocomposite film and nanoparticle size varying from 3 to 9 nm the approximate sub-layer thickness will be in the 15-25 nm range. The approximate light absorption trend is also shown in FIG. 3. Apparently due to the different energy quantization in quantum dots of different size the longer wavelength absorption is expected to shift toward the far end of the nanocomposite film thus providing a smoother absorption profile in the film. As shown in the lower portion of FIG. 3, corresponding energy level split facilitates quantum dot-assisted electron transport (hopping) toward the Back Metal thus enhancing the drift velocity and related quantum efficiency of the nanocomposite solar cell. In case of hole-conductive quantum dots the similar enhancement is expected for the hole transport (not shown in the figure).

### Example 3

In the embodiment shown in FIG. 5 the quantum dots in the sublayers of the nanocomposite film (photoactive layer) are arranged such that the smallest quantum dots are located closer to the first electrode while the biggest quantum dots are located closer to the second electrode (the Back Metal region). The bandgap of the quantum dots also varies inversely with size (the smallest quantum dot has the largest bandgap). The different colors of the quantum dots in each level correspond to their different compositions. The respective sub-layer thickness and the number of sub-layers depend on the total nanocomposite film thickness and the number of types of quantum dots. For instance for the 150 nm thick nanocomposite film and nanoparticle size varying from 3 to 9 nm the approximate sub-layer thickness will be in the 15-25 nm range. The approximate light absorption trend is also shown in FIG. 3. Apparently due to the different energy quantization in quantum dots of different size the longer wavelength absorption is expected to shift toward the far end of the nanocomposite film thus providing a smoother absorption profile in the film. As shown in the lower portion of FIG. 3, corresponding energy level split facilitates quantum dot-assisted electron transport (hopping) toward the Back Metal thus enhancing the drift velocity and related quantum efficiency of the nanocomposite solar cell. In case of hole-conductive quantum dots the similar enhancement is expected for the hole transport (not shown in the figure).

### Example 4

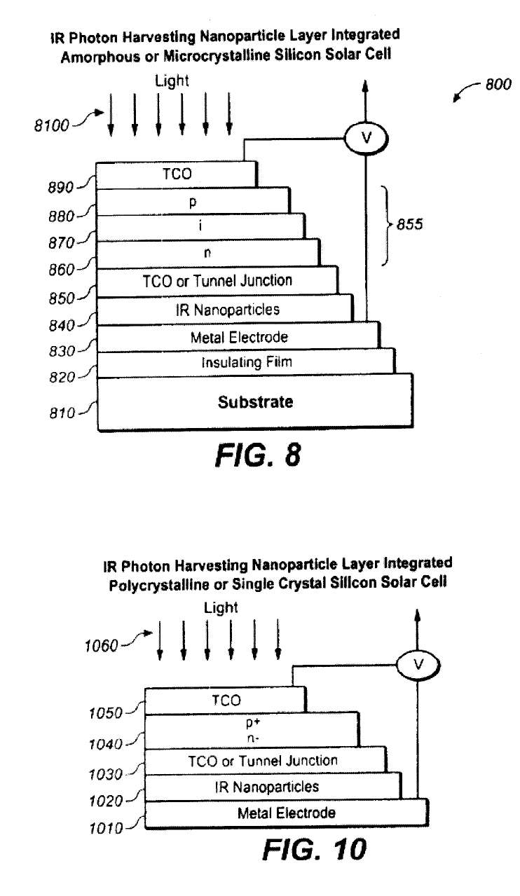

Referring to FIG. 8, one embodiment of a photovoltaic device 800 of the present invention is shown. In this embodiment photovoltaic device is built on a glass, metallic or plastic substrate 810 by depositing an insulating layer 820 and metal layer/second electrode 830 by methods well known in the art. Layer 840 is a first photoactive layer composed of nanocomposite film with quantum dots that absorb in the IR region 800-2,000 nm (with a bandgap of 1.2 ev and less) which is deposited on the metal layer/second electrode 830 optionally followed by a recombination layer which comprises a transparent conducting layer (for example ITO) or a tunnel-junction layer 850. First photoactive layer 840 has four sublayers (not shown) which are arranged in such a way that the quantum dots with the largest bandgap are located closer to the first electrode 890 while the quantum dots with smallest bandgap are located closer to the second electrode (830). These layers are followed by formation of a second photoactive layer 855 disposed above the first photoactive layer 840. In this embodiment, the second photoactive layer 855 is comprised of standard amorphous silicon layers that include n-type amorphous silicon 860, i-type amorphous silicon 870 and p-type amorphous silicon 880. Alternatively, second photoactive layer 855 may be comprised of microcrystalline silicon layers which also include n-type microcrystalline silicon, i-type microcrystalline silicon and p-type microcrystalline silicon. Second photoactive layer 855 may be formed by methods well known in the art. A transparent conducting layer (TCO)/first electrode 890 such as ITO is then deposited on top of the silicon layer. The photovoltaic device is oriented such that sunlight 8100 falls on the TCO/first electrode 890. The thickness of the amorphous or microcrystalline silicon layers 855 can be adjusted to maximize absorption in the visible region of the solar spectrum. The photovoltaic device described in this embodiment will harvest visible and IR photons from the solar spectrum resulting in higher conversion efficiency compared to the photovoltaic device design without integrating IR absorbing nanoparticles due to the multiple sublayers in photoactive layer 840.

Of particular advantage, a recombination layer or tunnel junction layer 850 is disposed between the first photoactive layer and the nanostructured layer. In some embodiments, the recombination layer may be comprised of a doped layer comprised of a material that conducts charge opposite that of the nanostructured material. Thus in some embodiments, the recombination layer will include a doped layer with a charge opposite that of a conducting polymer in the nanostructured material. Alternatively, the recombination layer is a doped layer comprised of a material that conducts charge opposite that of the nanoparticles in the nanostructured material. The recombination layer may further comprise a metal layer and/or an insulator layer coupled to doped layer.

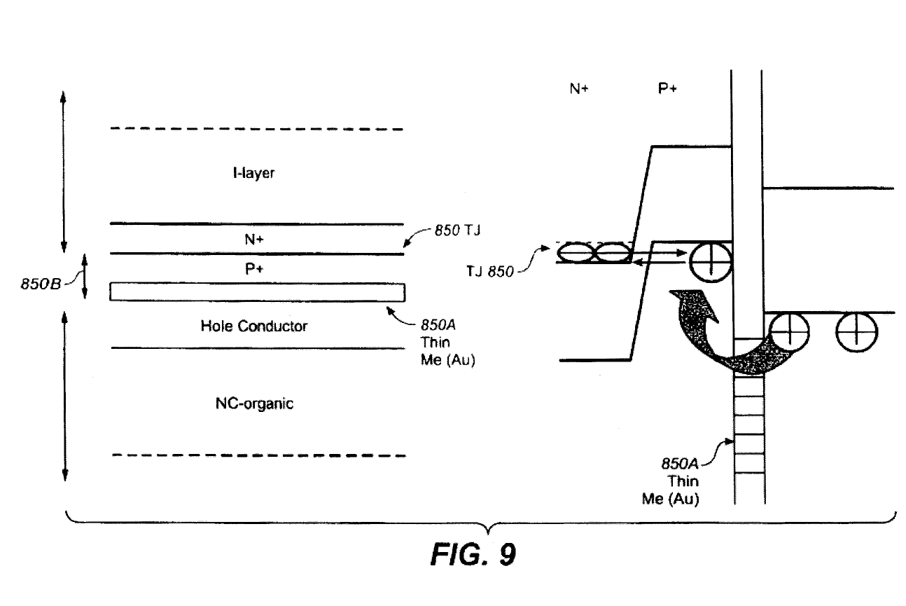

FIG. 9 illustrates recombination layer 850 in more detail. The recombination layer 850 is also sometimes referred to in the Examples below as tunnel junction layer. Nanostructured layer 840 is comprised of a hole conducting material, which may be hole conducting nanoparticles, or nanoparticles dispersed in a hole conducting material, such as a hole conducting polymer. Recombination layer 850 comprises a layer of metal/and or insulator and a layer of p doped material. In general, the recombination layer is a doped layer comprised of a material that conducts charge opposite that of the nanostructured layer. Thus, the recombination layer is a doped layer 850B comprised of a material that conducts charge opposite that of the nanoparticle, or of the conducting polymer depending on the material of the nanostructured layer 840. In some embodiments, the recombination layer further comprises a metal layer 850A coupled to doped layer 850B. Alternatively the recombination layer further comprises an insulating layer (not shown) coupled to doped layer 850B.

To provide a proper top and bottom cell connection for the photovoltaic device of the present invention an interface or recombination layer 850 is provided as generally illustrated in FIG. 9. In one embodiment, the recombination layer may have an additional layer of heavily doped amorphous silicon with the type of doping opposite to the nanostructured layers of the device and/or thin metal or insulating layer between the first photoactive layer and the nanostructured layer, which may be thought of as top and bottom solar cells. The recombination layer is configures to promote charge transport between the layers. Specifically, the recombination layer is configures such that the energy band configuration is favorable for a significant enhancement of the recombination rate between the holes from the bottom nanostructured layers 840 (also referred to as the bottom cell) and electrons from the first photoactive layers 855 (also referred to as the top cell). At the same time the SS participation in the e-h recombination process is suppressed by physical separation between the top and bottom cells.

Referring again to FIG. 9, the top cell has an extra heavily doped P+ layer 850B deposited on the heavily doped N+contact layer of the first photoactive layer 855, which in this embodiment is the N+ region of a P-I-N semiconductor. The above P+ and N+ layers form a tunnel junction at their interface with extra P+ layer 850B actually becoming a part of the hole conducting component of the bottom nanostructured layer 840. The first and nanostructured layers 855 and 840, respectively are physically separated by a thin tunnel film 850A of metal. In some embodiment, the metal film 850A is comprised of gold (Au) and preferably has a thickness in a range of approximately 5-15 A. Other metal films can be used in other embodiments provided they are thin enough to ensure direct hole tunneling from the nanostructured layers while not causing any significant optical or electrical losses at the interface. Alternatively, an insulting material may be used instead of a metal material. It should be noted that the present invention can be effectively used in photovoltaic device embodiments of opposite types of conductivity in which case extra N+ layer will replace the P+ layer of this embodiment and the nanostructured layer is designed in such that the upper contact layer is electron conducting and not hole conducting.

A corresponding band diagram is also shown in FIG. 9. It can be seen that with the recombination interface of the present invention, favorable energy conditions are created for the holes coming from the nanostructured or bottom cell to be transferred to the extra P+ layer of the top cell through the thin metal film, followed by direct tunneling and recombination with the electrons in the N+ layer of the top cell thus providing an efficient low resistive and minimal loss connection in series for the top and bottom cells. Hence the present invention represents an efficient solution for the problem of proper connection of top and bottom cell.

### Example 5

Another embodiment of a photovoltaic device of the present invention is illustrated in FIG. 10. Generally, in this embodiment, the first photoactive layer 1020 of nanostructured material is comprised of three sublayers (not shown) of different IR harvesting nanoparticles integrated with polycrystalline or single crystalline silicon layer. The polycrystalline or signal crystal silicon layer 1040 forms the second photoactive layer of a material that absorbs radiation substantially in the visible range of the solar spectrum. In this embodiment the polycrystalline silicon photovoltaic device is built by methods well known in the art by starting with an n-type polycrystalline wafer/second photoactive layer 1040 and doping it with a p-type dopant (alternately p-type single crystal wafer can be doped with n-type dopant) on one side of the wafer followed by a transparent conductor/first electrode or a conducting grid 1050. Optionally, a transparent conducting layer (ex: ITO) or a tunnel-junction layer 1030 is deposited on the polycrystalline silicon wafer on the opposite side of the first TCO/first electrode layer 1050. Sublayers of the first photoactive layer 1020 with an absorption in the IR region 800-2,000 nm (with a bandgap of 1.2 ev and less) are sequentially deposited on the TCO or tunnel junction layer/first electrode 1030 followed by a metal layer/second electrode 1010. This first photoactive layer 1020 has three sublayers which are arranged in such a way that the quantum dots with the largest bandgap are located closer to the first electrode 890 while the quantum dots with smallest bandgap are located closer to the second electrode 830. The thickness of polycrystalline silicon layers and the dopant concentrations can be adjusted to maximize absorption in the visible region of the solar spectrum. The photovoltaic device described in this embodiment will harvest IR photons from the solar spectrum resulting in higher conversion efficiency compared to the photovoltaic device design without sublayers in photoactive layer 1020.

### Example 6

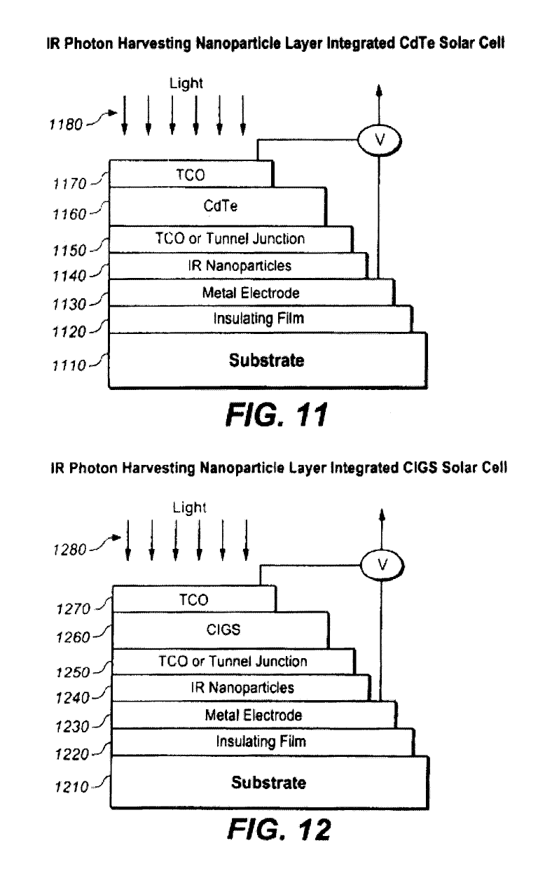

In yet another embodiment, a photovoltaic device is provided where the first photoactive layer is comprised of CdTe material as illustrated in FIG. 11. Here the first photoactive layer 1140 comprises two sublayers made of different IR harvesting nanoparticle layers. In this embodiment the photovoltaic device is built on a glass, metallic or plastic substrate 1110 by depositing an insulating layer 1120 and metal layer/second electrode 1130 by methods well known in the art. The sublayers of first photoactive layer 1140 with an absorption in the IR region 800-2,000 nm (with a bandgap 1.2 ev and less) are sequentially deposited on the metal layer/second electrode 1130 optionally followed by a transparent conducting layer (ex: ITO) or a tunnel-junction layer 1150, which comprises the recombination layer. This first photoactive layer has two sublayers which are arranged in such a way that the quantum dots with the largest bandgap are located closer to the first electrode while the quantum dots with smallest bandgap are located closer to the second electrode. These layers are followed by a CdTe second photoactive layer 1160 which is formed by methods well known in the art. A transparent conducting layer TCO/first electrode 1170 such as ITO is then deposited on top of the second photoactive layer. Photovoltaic device is oriented such that sunlight 1180 falls on the TCO/first electrode 1170. The thickness of the CdTe layer can be adjusted to maximize absorption in the visible region of the solar spectrum. The photovoltaic device described in this embodiment harvests IR photons from the solar spectrum resulting in higher conversion efficiency compared to the photovoltaic device design without the sublayer structure in photoactive layer 1140.

### Example 7

In a further embodiment as shown in FIG. 12, IR harvesting first photoactive layer 1240 with four sublayers is integrated with a CIGS second photoactive layer 1260. In this embodiment the photovoltaic device is built on a glass, metallic or plastic substrate 1210 by depositing an insulating layer 1220 and metal layer/second electrode 1230 by methods well known in the art. The sublayers of the first photoactive layer 1240 with an absorption in the IR region 800-2,000 nm (with a bandgap of 1.2 ev and less) are sequentially deposited on the metal layer/second electrode 1230 optionally, followed by a transparent conducting layer (ex: ITO) or a tunnel-junction layer 1250, which comprises the recombination layer. This first photoactive layer has four sublayers which are arranged in such a way that the quantum dots with the largest bandgap are located closer to the first electrode while the quantum dots with smallest bandgap are located closer to the second electrode. These layers are followed by a second photoactive layer including CIGS 1260 which are formed by methods well known in the art. A transparent conducting layer TCO/first electrode 1270 such as ITO is then deposited on top of the silicon layer. The photovoltaic device is oriented such that sunlight 1280 falls on the TCO/first electrode 1270. The thickness of the CIGS layer can be adjusted to maximize absorption in the visible region of the solar spectrum. The photovoltaic device described in this embodiment will harvest IR photons from the solar spectrum resulting in higher conversion efficiency compared to the photovoltaic device design without the sublayer structure in photoactive layer 1240.

### Example 8

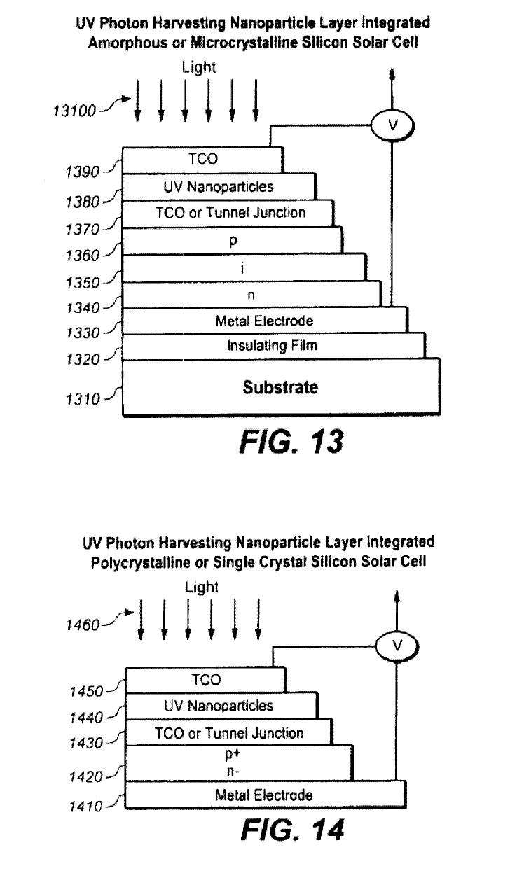

In another aspect of the present invention, a photovoltaic device is provided wherein a second photoactive layer (1340, 1350 and 1360) is comprised of a semiconductor material exhibiting absorption of radiation substantially in a visible region of the solar spectrum and a top first photoactive layer 1380 is comprised of three sublayers containing nanoparticles exhibiting absorption of radiation substantially in an UV region of the solar spectrum. A recombination layer is optionally disposed between the first and top layers, and configured to promote charge transport between the second and top layers. FIG. 13 shows a top first photoactive layer of UV harvesting nanoparticle layers integrated with a second photoactive layer comprised of amorphous or microcrystalline silicon layers. In this embodiment the photovoltaic device is built on a glass, metallic or plastic substrate 1310 by depositing an insulating layer 1320 and metal layer/second electrode 1330 by methods well known in the art. These layers are followed by standard amorphous or microcrystalline silicon layers which form the second photoactive layer in this embodiment and comprise n-type amorphous silicon 1340, i-type amorphous silicon 1350 and p-type amorphous silicon 1360 by methods well known in the art. Optionally, a transparent conducting layer TCO or tunnel-junction layer 1370 (in this case the recombination layer) is then deposited on top of the silicon layer as the recombination layer. The first nanoparticle layer 1380 with an absorption in the UV region (with a bandgap of 2 ev and higher) is deposited on the optional TCO or tunnel-junction layer 1370 followed by a transparent conducting layer/first electrode such as ITO 1390. This first photoactive layer has three sublayers which are arranged in such a way that the quantum dots with the largest bandgap are located closer to the first electrode while the quantum dots with smallest bandgap are located closer to the second electrode. The photovoltaic device is oriented such that sunlight (13100) falls on the TCO/first electrode (1390). Thickness of amorphous silicon layers can be adjusted to maximize absorption in the visible region of the solar spectrum. Photovoltaic device described in this embodiment will harvest UV photons from the solar spectrum resulting in higher conversion efficiency compared to the photovoltaic device design without the sublayer structure in photoactive layer 1380.

### Example 9

In another embodiment as shown in FIG. 14, UV harvesting nanoparticle sublayers in first photoactive layer 1440 are integrated with polycrystalline or single crystal silicon layers 1420. In this embodiment polycrystalline or single crystal silicon photovoltaic device is built by methods well known in the art by starting with an n-type polycrystalline wafer/second photoactive layer 1420 and doping it with a p-type dopant (alternately p-type single crystal wafer can be doped with n-type dopant) on one side of the wafer followed by a metal layer/second electrode 1410. This first photoactive layer has five sublayers which are arranged in such a way that the quantum dots with the largest bandgap are located closer to the first electrode 1450 while the quantum dots with smallest bandgap are located closer to the second electrode 1410. Optionally, a transparent conducting layer (ex: ITO) or a tunnel-junction layer 1430 (also referred to as recombination layer) is deposited on the polycrystalline silicon wafer on the opposite side of the metal layer/second electrode 1410. Sublayers of first photoactive layer 1440 with an absorption in the UV region (with a bandgap of 2 ev and higher) are deposited on the optional TCO or tunnel junction layer 1430 followed by a TCO layer/first electrode 1450. Thickness of polycrystalline silicon layers and the dopant concentrations can be adjusted to maximize absorption in the visible region of the solar spectrum. Photovoltaic device described in this embodiment will harvest UV photons from the solar spectrum resulting in higher conversion efficiency compared to the photovoltaic device design without the sublayer structure in photoactive layer 1380.

### Example 10

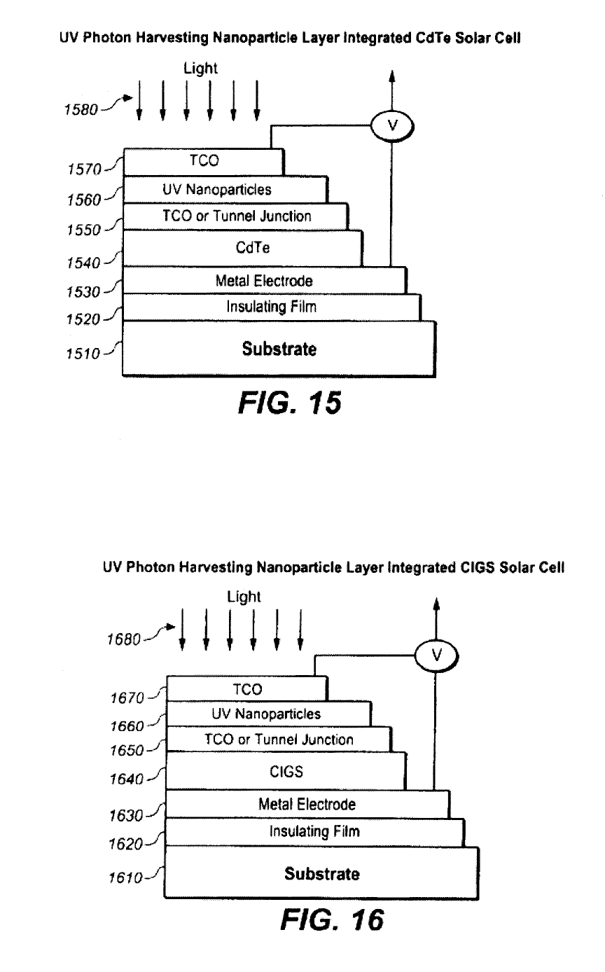

In another embodiment as shown in FIG. 15, UV harvesting photoactive layer 1560 is integrated with a CdTe second photoactive layer 1540. In this embodiment photovoltaic device is built on a glass, metallic or plastic substrate 1510 by depositing an insulating layer 1520 and metal layer/second electrode 1530 followed by the CdTe second photoactive layer 1540 by methods well known in the art. Optionally, a transparent conducting layer (ex: ITO) or a tunnel-junction layer 1550 (in this case the recombination layer) is deposited on the CdTe second photoactive layer 1540 followed by the nanoparticle sublayers of first photoactive layer 1560 with an absorption in the UV region (with a bandgap of 2 ev and higher) followed by a transparent conducting layer TCO/first electrode 1570 such as ITO is then deposited on top of the first photoactive layer. This first photoactive layer has three sublayers which are arranged in such a way that the quantum dots with the largest bandgap are located closer to the first electrode while the quantum dots with smallest bandgap are located closer to the second electrode. Photovoltaic device is oriented such that sunlight 1580 falls on the TCO/first electrode 1570. The thickness of CdTe layer/second photoactive layer can be adjusted to maximize absorption in the visible region of the solar spectrum. The photovoltaic device described in this embodiment will harvest UV photons from the solar spectrum resulting in higher conversion efficiency compared to the photovoltaic device design without the sublayer structure of first photoactive layer 1560.

### Example 11

In yet another embodiment as shown in FIG. 16, UV harvesting photoactive layer 1660 is integrated with a CIGS second photoactive layer 1640. In this embodiment photovoltaic device is built on a glass, metallic or plastic substrate 1610 by depositing an insulating layer 1620 and metal layer/second electrode 1630 followed by CIGS second photoactive layer 1640 by methods well known in the art. Optionally, a transparent conducting layer (ex: ITO) or a tunnel-junction layer 1650 (also referred to as recombination layer) is deposited on the CIGS layer/second photoactive layer 1640 followed by the sublayers of the first photoactive layer 1660 with an absorption in the UV region (with a bandgap of 2 ev and higher) followed by a transparent conducting layer TCO/first electrode 1670 such as ITO is then deposited on top of the nanoparticle layer. This first photoactive layer has four sublayers which are arranged in such a way that the quantum dots with the largest bandgap are located closer to the first electrode while the quantum dots with smallest bandgap are located closer to the second electrode. Photovoltaic device is oriented such that sunlight 1680 falls on the TCO/first electrode 1670. Thickness of CIGS layer/second photoactive layer can be adjusted to maximize absorption in the visible region of the solar spectrum. Photovoltaic device described in this embodiment will harvest visible and UV photons from the solar spectrum resulting in higher conversion efficiency compared to the photovoltaic device design without integrating UV absorbing nanoparticles.

### Example 12

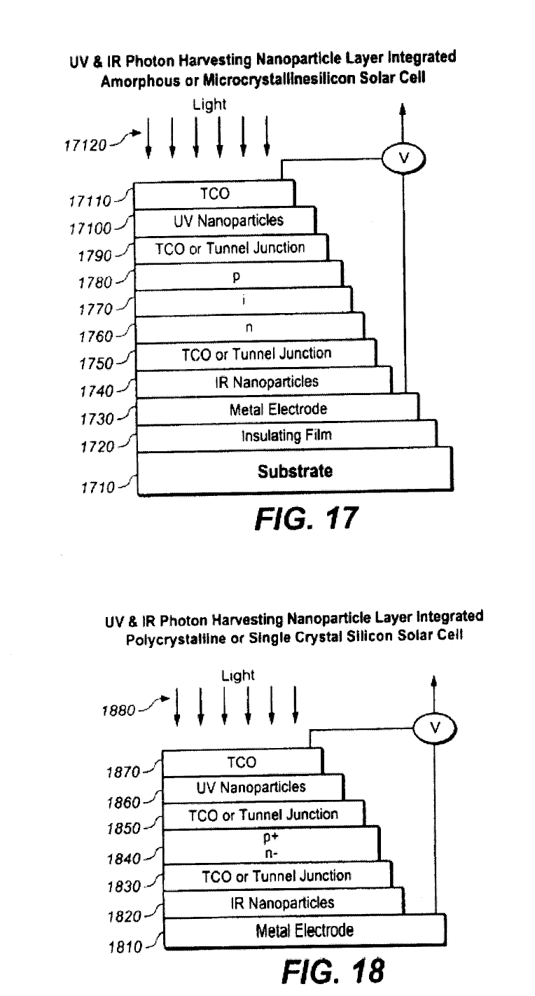

FIG. 17 shows a first photoactive layer 17100 of UV harvesting nanoparticle sublayers (not shown) and a second photoactive layer 1740 of IR harvesting nanoparticle sublayer 1740 with a photoactive layer (1760, 1770 and 1780) disposed there between. In this embodiment, the third photoactive layer comprises amorphous or microcrystalline silicon layers. In this embodiment photovoltaic device is built on a glass, metallic or plastic substrate 1710 by depositing an insulating layer 1720 and metal layer/second electrode 1730 by methods well known in the art. Second photoactive layer 1740 with an absorption in the IR region 800-2,000 nm (with a bandgap less than 1.2 ev) is deposited on the metal layer/second electrode 1730 optionally followed by a transparent conducting layer (ex: ITO) or a tunnel-junction layer (or recombination layer) 1750. This second photoactive layer has four sublayers which are arranged in such a way that the quantum dots with the largest bandgap are located closer to the first electrode while the quantum dots with smallest bandgap are located closer to the second electrode. These layers are followed by depositing of a third photoactive layer, in this case standard amorphous or microcrystalline silicon layers that comprise n-type amorphous silicon 1760, i-type amorphous silicon 1770 and p-type amorphous silicon 1780, formed by methods well known in the art. Optionally, a transparent conducting layer TCO 1790 or tunnel-junction layer is then deposited on top of the silicon layer. First photoactive layer 17100 with an absorption in the UV region (with a bandgap higher than 2 ev) is deposited on the TCO or tunnel-junction layer (1790) followed by a transparent conducting layer such as ITO/first electrode 17110. The first photoactive layer has four sublayers which are arranged in such a way that the quantum dots with the largest bandgap are located closer to the first electrode while the quantum dots with the smallest bandgap are located closer to the second electrode. The photovoltaic device is oriented such that sunlight 17120 falls on the TCO 1790. Thickness of amorphous silicon layers can be adjusted to maximize absorption in the visible region of the solar spectrum. Photovoltaic device described in this embodiment will harvest UV and IR photons from the solar spectrum resulting in higher conversion efficiency compared to the photovoltaic device design without the sublayer structure of the first and second photoactive layers respectively.

### Example 13

Another embodiment is depicted in FIG. 18 which shows nanoparticle-/sublayer-based UV & IR first and second layers 1860 and 1820 are integrated with a third polycrystalline or single crystal silicon photoactive layer 1840. In this embodiment polycrystalline or single crystal silicon photovoltaic device is built by methods well known in the art by starting with an n-type polycrystalline wafer/third photoactive layer 1840 and doping it with a p-type dopant (alternately p-type single crystal wafer can be doped with n-type dopant) on one side of the wafer optionally followed by an TCO or tunnel-junction layer 1830. Optionally, a transparent conducting layer (ex: ITO) or a tunnel-junction layer (also referred to as recombination layer) 1850 is deposited on the polycrystalline silicon wafer/third photoactive layer 1840 on the opposite side of the first TCO or tunnel-junction layer 1830. First photoactive layer 1860 with an absorption in the UV region (with a bandgap higher than 2 ev) is deposited on the TCO or tunnel junction layer 1830 followed by a TCO layer/first electrode 1870. The first photoactive layer has five sublayers which are arranged in such a way that the quantum dots with the largest bandgap are located closer to the first electrode while the quantum dots with the smallest bandgap are located closer to the second electrode. Second photoactive layer 1820 with an absorption in the IR region (with a bandgap less than 1.2 ev) is deposited on the TCO or tunnel junction layer 1850 followed by a metal electrode layer/second electrode 1810. The first photoactive layer has three sublayers which are arranged in such a way that the quantum dots with the largest bandgap are located closer to the first electrode while the quantum dots with smallest bandgap are located closer to the second electrode. Thickness of polycrystalline silicon layers and the dopant concentrations can be adjusted to maximize absorption in the visible region of the solar spectrum. The photovoltaic device described in this embodiment will harvest UV and IR photons from the solar spectrum resulting in higher conversion efficiency compared to the photovoltaic device design without the sublayer structure of the first and second photoactive layers, respectively.

### Example 14

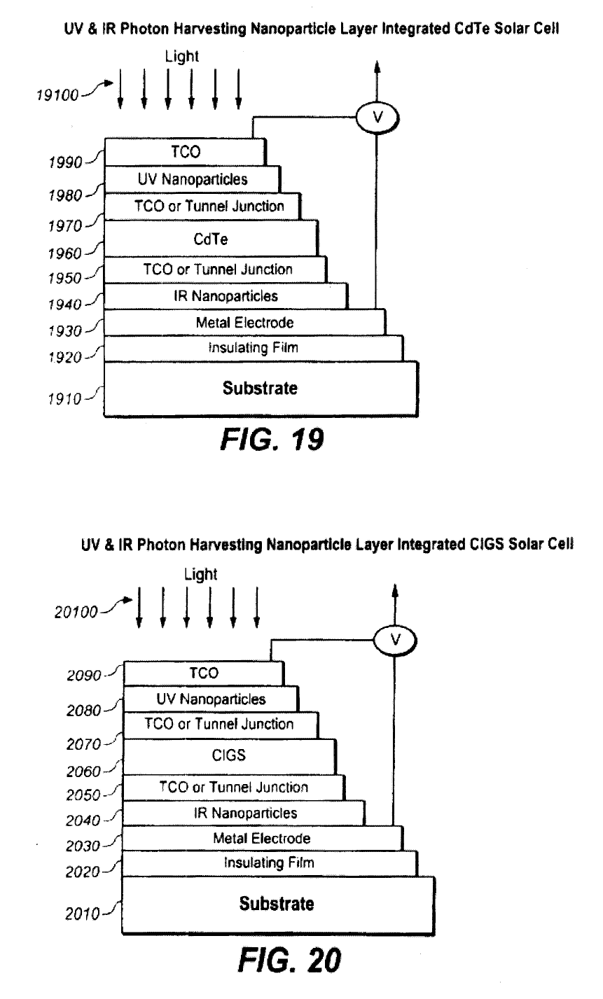

FIG. 19 illustrates another embodiment where nanoparticle-/sublayer-based UV & IR first and second photoactive layers 1980 and 1940 are integrated with CdTe layer 1960. In this embodiment photovoltaic device is built on a glass, metallic or plastic substrate 1910 by depositing an insulating layer 1920 and metal layer/second electrode 1930 followed by second photoactive layer 1940 with an absorption in the IR region (with a bandgap less than 1.2 ev) followed by a transparent conducting layer TCO layer 1950 or tunnel-junction layer. The second photoactive layer 1940 has five sublayers which are arranged in such a way that the quantum dots with the largest bandgap are located closer to the first electrode while the quantum dots with smallest bandgap are located closer to the second electrode. The CdTe third photoactive layer 1960 is then deposited on TCO or tunnel-junction layer (or recombination layer) 1950 by methods well known in the art. A transparent conducting layer (ex: ITO) or a tunnel-junction layer 1970 is deposited on the CdTe layer/third photoactive layer 1960 followed by first photoactive layer 1980 with an absorption in the UV region (with a bandgap greater than 2 ev) followed by a transparent conducting layer TCO/first electrode 1990 such as ITO is then deposited on top of the nanoparticle layer. The first photoactive layer has three sublayers which are arranged in such a way that the quantum dots with the largest bandgap are located closer to the first electrode while the quantum dots with smallest bandgap are located closer to the second electrode. Photovoltaic device is oriented such that sunlight 19100 falls on the TCO/first electrode 1990. Thickness of CdTe layer/third photoactive layer can be adjusted to maximize absorption in the visible region of the solar spectrum. Photovoltaic device described in this embodiment will harvest UV and IR photons from the solar spectrum resulting in higher conversion efficiency compared to the photovoltaic device design without the sublayer structure of photoactive layers 1940 and 1980.

### Example 15

FIG. 20 illustrates yet another embodiment where UV & IR nanoparticle sublayer based on photoactive layers 2080 and 2040 are integrated with CIGS layer 2060. In this embodiment photovoltaic device is built on a glass, metallic or plastic substrate 2010 by depositing an insulating layer 2020 and metal layer/second electrode 2030 followed by nanoparticle second photoactive layer 2040 with an absorption in the IR region (with a bandgap less than 1.2 ev) followed by a transparent conducting layer TCO layer or tunnel-junction layer (or recombination layer) 2050. The second photoactive layer has six sublayers which are arranged in such a way that the quantum dots with the largest bandgap are located closer to the first electrode while the quantum dots with smallest bandgap are located closer to the second electrode. CIGS layers 2060 are then deposited on TCO or tunnel-junction layer 2050 by methods well known in the art. A transparent conducting layer (ex: ITO) or a tunnel-junction layer 2070 is deposited on the CIGS layer/third photoactive layer 2060 followed by nanoparticle layer/second photoactive layer 2080 with an absorption in the UV region (with a bandgap greater than 2 ev) followed by a transparent conducting layer TCO/first electrode 2090 such as ITO is then deposited on top of the nanoparticle layer. The first photoactive layer has three sublayers which are arranged in such a way that the quantum dots with the largest bandgap are located closer to the first electrode while the quantum dots with smallest bandgap are located closer to the second electrode. Photovoltaic device is oriented such that sunlight 20100 falls on the TCO/first electrode 2090. Thickness of CIGS layer/second photoactive layer can be adjusted to maximize absorption in the visible region of the solar spectrum. Photovoltaic device described in this embodiment will harvest UV and IR photons from the solar spectrum resulting in higher conversion efficiency compared to the photovoltaic device design without the sublayer structures in layers 2080 and 2040.

### Example 16

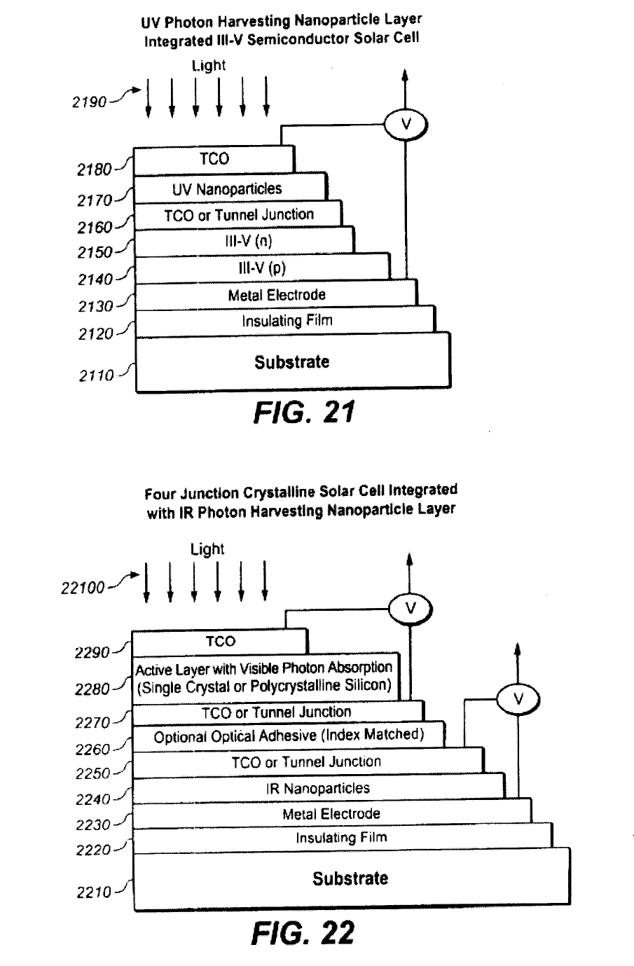

In another aspect, compound semiconductor materials may be employed as the photoactive layer which absorbs radiation substantially in the visible region of the solar spectrum. FIG. 21 illustrates a photovoltaic device with a UV harvesting nanoparticle/sublayered first photoactive layer 7170 (ex: InP quantum dots) integrated with III-V semiconductor layers 2140 and 2150 (ex: GaAs). In this embodiment photovoltaic device is built on a substrate 2110 by depositing an insulating layer 2120 and metal layer/second electrode 2130 by methods well known in the art. These layers are followed by III-V semiconductor layers/second photoactive layer that consist of p-type semiconductor 2140 and n-type semiconductor 2150 by methods well known in the art. A transparent conducting layer TCO 2160 or tunnel-junction layer is then deposited on top of the III-V layer. First photoactive layer 2170 with an absorption in the UV region (with a bandgap higher than 2 ev) is deposited on the TCO or tunnel-junction layer (also referred to as recombination layer) 2160 followed by a transparent conducting layer/first electrode 2180. The first photoactive layer has four sublayers which are arranged in such a way that the quantum dots with the largest bandgap are located closer to the first electrode while the quantum dots with smallest bandgap are located closer to the second electrode. Photovoltaic device is oriented such that sunlight 2190 falls on the TCO/first electrode 2180. Photovoltaic device described in this embodiment will harvest UV photons from the solar spectrum resulting in higher conversion efficiency compared to the photovoltaic device design without the sublayer structure in the first photoactive layer.

### Example 17

Some embodiments of the present invention provide a four junction photovoltaic device. FIG. 22 illustrates an IR harvesting nanoparticle photovoltaic device containing first photoactive layer 2240 and a crystalline (single crystal or polycrystalline) photovoltaic device integrated to form a four junction photovoltaic device. In this embodiment crystalline silicon photovoltaic device is built by methods well known in the art by starting with an n-type crystalline silicon wafer/second photoactive layer 2280 and doping it with a p-type dopant (alternately p-type silicon wafer can be doped with n-type dopant) on one side of the wafer followed by a transparent conducting layer/third electrode or tunnel junction layer 2270. The crystalline silicon photovoltaic device is completed by depositing a transparent conducting layer (ex: ITO)/first electrode 2290 on the silicon wafer on the opposite side of the first TCO layer/third electrode 2270. The photovoltaic device containing a first photoactive layer with sublayers of an IR absorbing nanoparticles is built by starting with a substrate (glass, metal or plastic) 2210 and depositing a dielectric layer 2220 followed by metal layer/second electrode 2230 by using standard methods known in the art. A first photoactive layer 2240 with an absorption in the IR region (with a bandgap less than 1 ev) is deposited on the metal layer/second electrode 2230 followed by a TCO/fourth electrode or tunnel junction layer (in this case the second recombination layer) 2250. The first photoactive layer has five sublayers which are arranged in such a way that the quantum dots with the largest bandgap are located closer to the first electrode while the quantum dots with smallest bandgap are located closer to the second electrode. A four junction tandem cell shown in FIG. 22 is built by combining the crystalline silicon photovoltaic device and the IR absorbing nanoparticle photovoltaic device. An optical adhesive layer 2260 can be optionally used to bond the two cells together. Relative performance of the individual cells can be adjusted to maximize absorption in the visible and IR region of the solar spectrum. Photovoltaic device described in this embodiment will harvest IR photons from the solar spectrum resulting in higher conversion efficiency compared to the photovoltaic device design without integrating a photovoltaic device without the sublayer structures of layer 2240.

### Example 18

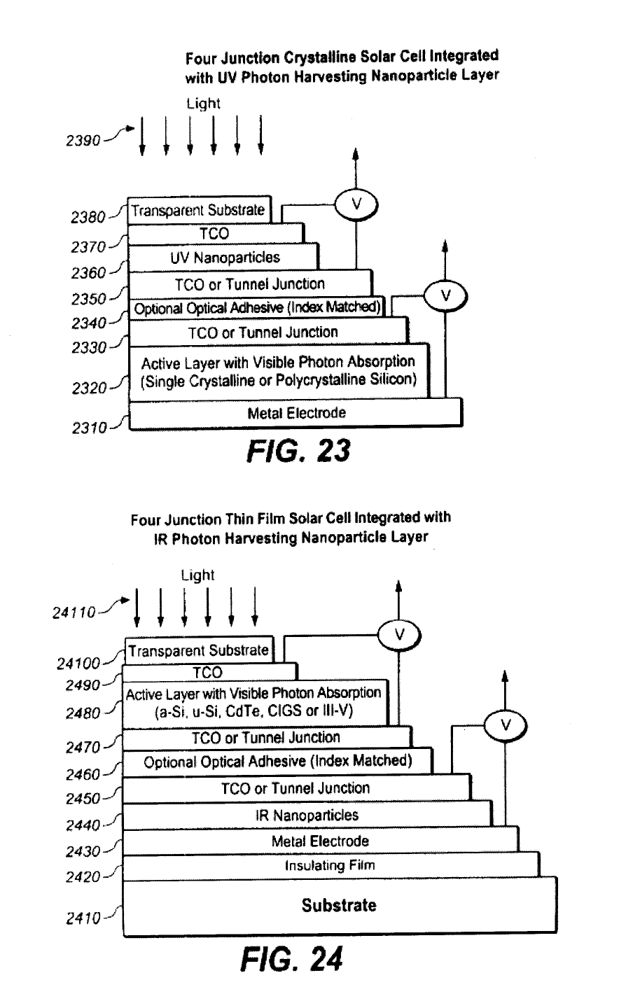

FIG. 23 illustrates another embodiment where UV harvesting nanoparticle photovoltaic device and crystalline (single crystal or polycrystalline) silicon photovoltaic device are integrated to form a four junction photovoltaic device. In this embodiment crystalline silicon photovoltaic device is built by methods well known in the art by starting with an n-type crystalline silicon wafer/second photoactive layer 2320 and doping it with a p-type dopant (alternately p-type silicon wafer can be doped with n-type dopant) on one side of the wafer followed by a metal layer/second electrode 2310. The crystalline silicon photovoltaic device is completed by depositing a transparent conducting layer/fourth electrode (ex: ITO) or a tunnel-junction layer (in this case the first recombination layer) 2330 on the silicon wafer on the opposite side of the metal layer/second electrode 2310. Photovoltaic device containing UV absorbing nanoparticles is built by starting with a transparent substrate (glass or plastic) 2380 and depositing a transparent conducting TCO layer/first electrode 2370 by using standard methods known in the art. A nanoparticle layer/first photoactive layer 2360 with an absorption in the IR region (with a bandgap less than 2 ev) is deposited on the TCO layer/first electrode 2370 followed by a TCO/third electrode or tunnel junction layer (in this case the second recombination layer) 2350. The first photoactive layer has six sublayers which are arranged in such a way that the quantum dots with the largest bandgap are located closer to the first electrode while the quantum dots with smallest bandgap are located closer to the second electrode. A four junction tandem cell shown in FIG. 23 is built by combining the crystalline silicon photovoltaic device and the IR absorbing nanoparticle photovoltaic device. An optical adhesive layer 2340 can be optionally used to bond the two cells together. Relative performance of the individual cells can be adjusted to maximize absorption in the visible and UV region of the solar spectrum. Photovoltaic device described in this embodiment will harvest UV photons from the solar spectrum resulting in higher conversion efficiency compared to the photovoltaic device design without integrating a photovoltaic device containing the sublayer structure in layer 2360.

### Example 19

FIG. 24 depicts yet another embodiment where IR harvesting nanoparticle photovoltaic device and a thin film (a-Si, u-Si, CdTe, CIGS, III-V) photovoltaic device is integrated to form a four junction photovoltaic device. In this embodiment thin film photovoltaic device is built by methods well known in the art by starting with a transparent substrate 24100 and depositing transparent conducting layer/first electrode 2490 followed by active thin film layer/second photoactive layer 2480 and a transparent conductor/third electrode or tunnel junction layer (the first recombination layer) 2470. Photovoltaic device containing IR absorbing nanoparticles is built by starting with a substrate (glass, metal or plastic) 2410 and depositing a dielectric layer 2420 followed by metal layer/second electrode 2430 by using standard methods known in the art. A nanoparticle layer/first photoactive layer 2440 with an absorption in the IR region (with a bandgap less than 1 ev) is deposited on the metal layer/first electrode 2430 followed by a TCO/fourth electrode or tunnel junction layer (the second recombination layer) 2450. The first photoactive layer has four sublayers which are arranged in such a way that the quantum dots with the largest bandgap are located closer to the first electrode while the quantum dots with smallest bandgap are located closer to the second electrode. A four junction tandem cell shown in FIG. 24 is built by combining the crystalline silicon photovoltaic device and the IR absorbing nanoparticle photovoltaic device. An optical adhesive layer 2460 can be optionally used to bond the two cells together. Relative performance of the individual cells can be adjusted to maximize absorption in the visible and IR region of the solar spectrum. Photovoltaic device described in this embodiment will harvest IR photons from the solar spectrum resulting in higher conversion efficiency compared to the photovoltaic device design without the sublayer structure in layer 2440.

### Example 20

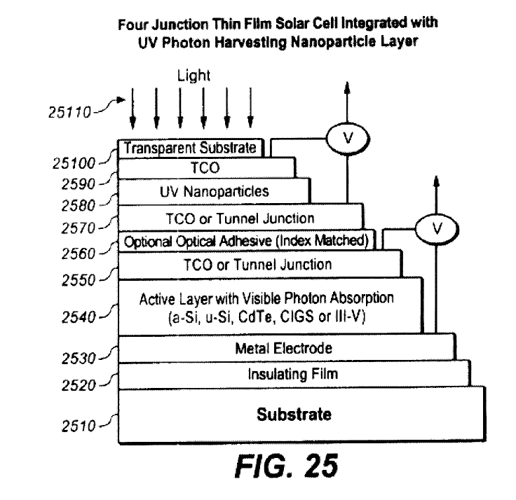

An additional embodiment of a four junction photovoltaic device according to embodiments of the present invention is shown in FIG. 25 where UV harvesting nanoparticle photovoltaic device and a thin film (a-Si, u-Si, CdTe, CIGS, III-V) photovoltaic device is integrated to form a four junction photovoltaic device. In this embodiment thin film photovoltaic device is built by methods well known in the art by starting with a transparent substrate 25100 and depositing transparent conducting layer/first electrode 2590 followed by active thin film layer/first photoactive layer 2580 and a transparent conductor/third electrode or tunnel junction layer (e.g. first recombination layer) 2570. The first photoactive layer has three sublayers which are arranged in such a way that the quantum dots with the largest bandgap are located closer to the first electrode while the quantum dots with smallest bandgap are located closer to the second electrode. Photovoltaic device containing UV absorbing nanoparticles is built by starting with a substrate (glass, metal or plastic) 2510 and depositing a dielectric layer 2520 followed by metal layer/second electrode 2530 by using standard methods known in the art. An active layer with visible photon absorption/second photoactive layer 2540 with an absorption in the UV region (with a bandgap less than 1 ev) is deposited on the metal layer 2530 followed by a TCO/fourth electrode or tunnel junction layer (e.g, second recombination layer) 2550. A four junction tandem cell shown in FIG. 25 is built by combining the crystalline silicon photovoltaic device and the UV absorbing nanoparticle photovoltaic device. An optical adhesive layer 2560 can be optionally used to bond the two cells together. Relative performance of the individual cells can be adjusted to maximize absorption in the visible and UV region of the solar spectrum. Photovoltaic device described in this embodiment will harvest UV photons from the solar spectrum resulting in higher conversion efficiency compared to the photovoltaic device design without the sublayer structure of layer 2580.

### Example 21

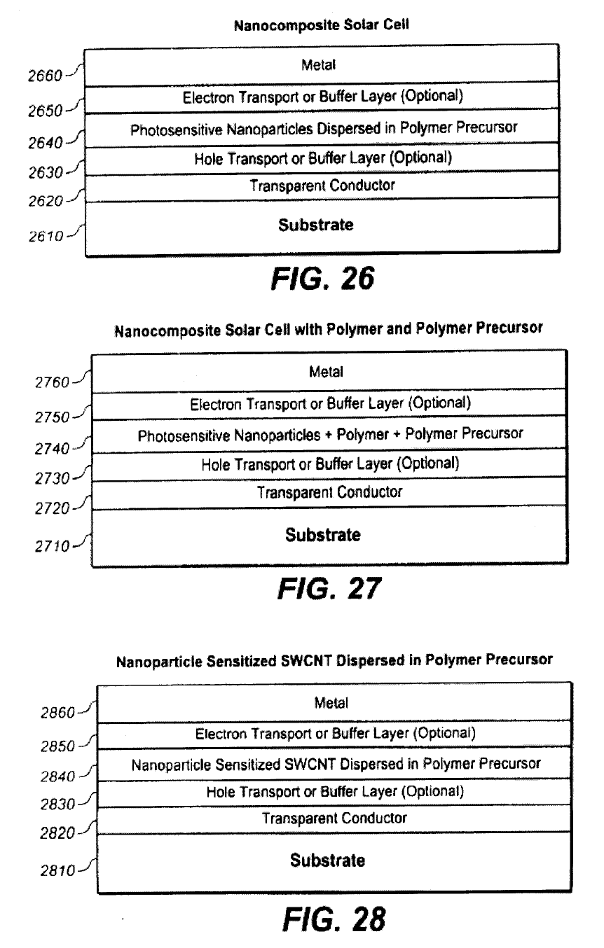

In a further aspect, embodiments of the present invention provides a photovoltaic device with functionalized nanoparticles, comprising: a first photoactive layer comprised of semiconductor material exhibiting absorption of radiation substantially in a visible region of the solar spectrum, and on or more photoactive layer comprised of nanostructured material exhibiting absorption of radiation substantially in a UV visible and/or IR region of the solar spectrum where one or more of the photoactive layers made of sublayers with different nanoparticles. FIG. 26 illustrates one embodiment of a nanocomposite photovoltaic device. This photovoltaic device is formed by coating a thin nanocomposite layer/first photoactive layer 2640 containing photosensitive nanoparticles and precursor of a high mobility polymer such as pentacene on a glass substrate 2610 coated with a transparent conductor/first electrode 2620 such as ITO followed by the deposition of cathode metal layer/second electrode 2660. Photosensitive nanoparticles can be made from Group IV, II-IV, II-VI, IV-VI, III-V materials. Examples of photosensitive nanoparticles include, but are not limited to any one or more of: Si, Ge, CdSe, PbSe, ZnSe, CdTe, CdS, or PbS. Nanoparticle sizes can be varied, for example in a range of approximately 2 nm to 10 nm to obtain a range of bandgaps in the sublayers (if present). These nanoparticles can be prepared by methods known in the art. Nanoparticles can be functionalized by methods known in the art. Examples of suitable functional groups include, but are not limited to: carboxylic (—COOH), amine (—NH₂), Phosphonate (—PO₄), Sulfonate (—HSO₃), Aminoethanethiol, etc. Nanocomposite layer 2640 containing two or more sublayers of different photosensitive nanoparticles dispersed in precursor of high mobility polymer such as pentacene can be deposited on ITO coated glass substrate sequentially by spin coating or other well known solution processing techniques. Precursor in the nanocomposite first photoactive layer 2640 is polymerized by heating the films to appropriate temperatures to initiate polymerization of pentacene precursor. If a UV polymerizable precursor is used the polymerization can be achieved by exposing the film to UV from the ITO side 2620 of FIG. 26. In this device electron hole pairs are generated when sunlight is absorbed by the nanoparticles and the resulting electrons are rapidly transported by the high mobility polymer such as pentacene to the cathode for collection. This rapid removal of electrons from the electron-hole pairs generated by the nanoparticles eliminates the probability of electron-hole recombination commonly observed in nanoparticle based photovoltaic device devices.

According to the embodiments shown in FIG. 26, hole injecting/transporting interface layer or a buffer layer 2630 may be disposed between ITO 2620 and nanocomposite layer 2640. Alternatively, electron injecting/transporting interface layer, also referred to recombination layer, 2650 may be disposed between metal layer 2660 and nanocomposite layer 2640.

### Example 22

FIG. 27 depicts another embodiment of nanocomposite photovoltaic device. This photovoltaic device is fabricated by coating a nanocomposite first photoactive layer 2740 comprising photosensitive nanoparticles, a high mobility polymer such as PVK or P3HT and a precursor of a high mobility polymer 2740 such as pentacene on a glass substrate 2710 coated with a transparent conductor/first electrode 2720 such as ITO followed by the deposition of cathode metal layer/second electrode 2760. Photosensitive nanoparticles comprise Group IV, II-IV, II-VI, IV-VI, III-V materials. Examples of photosensitive nanoparticles include, but are not limited to any one or more of: Si, Ge, CdSe, PbSe, ZnSe, CdTe, CdS or PbS. Nanoparticle sizes can be varied (for example in a range of approximately 2 nm to 10 nm) to obtain a range of bandgaps. These nanoparticles can be prepared by methods known in the art. Nanoparticles can be functionalized by methods known in the art. Functional groups include, but are not limited to: carboxylic (—COOH), amine (—NH₂), Phosphonate (—PO₄), Sulfonate (—HSO₃), Aminoethanethiol, etc. Nanocomposite first photoactive layer 2740 of photosensitive nanoparticles dispersed in high mobility polymer such as PVK or P3HT and a precursor of high mobility polymer such as pentacene can be deposited on ITO coated glass substrate by spin coating or other known solution processing techniques. Nanocomposite first photoactive layer 2740 contains multiple sublayers with different nanoparticles. In some embodiments, the precursor in the nanocomposite first photoactive layer 2740 is polymerized by heating the films to appropriate temperatures to initiate polymerization of pentacene precursor. If a UV polymerizable precursor is used the polymerization can be achieved by exposing the film to UV from the ITO side 2720.

Additionally, in some embodiments hole injecting/transporting interface layer or a buffer layer 2730 can be used between ITO 2720 and nanocomposite layer 2740. In an alternative embodiment, electron injecting/transporting interface layer 2750 can be used between metal layer 2760 and nanocomposite layer 2740.

### Example 23

In some embodiments, the photoactive layers and/or sublayers are comprised of a mixture of photosensitive nanoparticles and conductive nanoparticles. One, or both of, the photosensitive and conductive nanoparticles may be functionalized. Examples of conductive nanoparticles are comprised of any one or more of: single wall carbon nanotubes (SWCNT), TiO₂ nanotubes, or ZnO nanowires. Examples of photosensitive nanoparticles are comprised of any one or more of: CdSe, ZnSe, PbSe, InP, Si, Ge, SiGe, or Group III-V materials.

FIG. 28 illustrates an embodiment of nanocomposite photovoltaic device built by coating a thin first photoactive layer 2840 containing photosensitive nanoparticles attached to a conducting nanostructure dispersed in a precursor of a high mobility polymer such as pentacene on a glass substrate 2810 coated with a transparent conductor/first electrode 2820 such as ITO followed by the deposition of cathode metal layer/second electrode 2860. Photosensitive nanoparticles can be made from Group IV, II-IV, II-VI, IV-VI, III-V materials. Examples of photosensitive nanoparticles include Si, Ge, CdSe, PbSe, ZnSe, CdTe, CdS, PbS. Nanoparticle sizes can be varied (for example: 2-10 nm) to obtain a range of bandgaps. These nanoparticles can be prepared by following the methods well known in the art. Nanoparticles can be functionalized by following the methods well known in the art. Functional groups can include carboxylic (—COOH), amine (—NH₂), Phosphonate (—PO₄), Sulfonate (—HSO₃), Aminoethanethiol, etc. Conducting nanostructures can be made from carbon nanotubes (SWCNT), TiO₂ nanotubes or ZnO nanowires. Conducting nanostructures can be functionalized to facilitate the attachment of photosensitive nanoparticles to the surface of conducting nanostructures. Nanocomposite first photoactive layer 2840 of photosensitive nanoparticles are attached to conducting nanostructures and dispersed in precursor of high mobility polymer such as pentacene. The sublayers of photoactive layer 2840 are sequentially deposited on ITO coated glass substrate by spin coating or other known solution processing techniques. A precursor in first photoactive layer 2840 is polymerized by heating the films to appropriate temperatures to initiate polymerization of precursor. If a UV polymerizable precursor is used the polymerization can be achieved by exposing the film to UV from the ITO side/first electrode 2820. Additionally hole injecting/transporting interface layer or a buffer layer 2830 can be employed between ITO/first electrode 2820 and nanocomposite layer 2840. In another embodiment, electron injecting/transporting interface layer 2850 can be used between metal layer/second electrode 2860 and nanocomposite layer 2840.

### Example 24

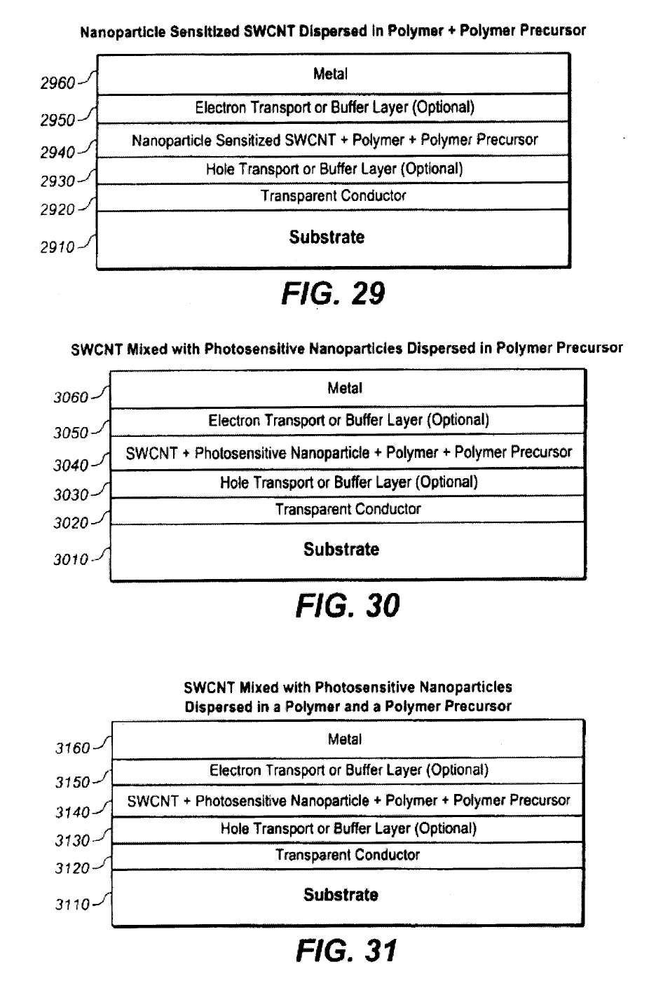

A further embodiment of nanocomposite photovoltaic device is shown in FIG. 29. This photovoltaic device can be built as in Example 23 by coating a nanocomposite photoactive layer 2940 containing 20 or more sublayers of different photosensitive nanoparticles attached to a conducting nanostructure dispersed in a high mobility polymer such as PVK or P3HT and a precursor of a high mobility polymer such as pentacene 2940 on a glass substrate 2910 coated with a transparent conductor/first electrode 2920 such as ITO followed by the deposition of cathode metal layer/second electrode 2960.

### Example 25

Yet a further embodiment of nanocomposite photovoltaic device is shown in FIG. 30. This photovoltaic device can be built by coating nanocomposite first photoactive layer 3040 containing two or more sublayers of different photosensitive nanoparticles and conducting nanostructure dispersed in a precursor of a high mobility polymer such as pentacene on a glass substrate 3010 coated with a transparent conductor/first electrode 3020 such as ITO followed by the deposition of cathode metal layer/second electrode 3060.

### Example 26

FIG. 31 depicts yet another embodiment of nanocomposite photovoltaic device. This photovoltaic device can be built in Example 23 by coating a nanocomposite first photoactive layer 3140 comprising two or more sublayers of different photosensitive nanoparticles and conducting nanostructures dispersed in a high mobility polymer such as PVK or P3HT and a precursor of a high mobility polymer such as pentacene 3140 on a glass substrate 3110 coated with a transparent conductor/first electrode 3120 such as ITO followed by the deposition of cathode metal layer/second electrode 3160.

The above embodiments are some examples of the applying the present invention. It will be understood to any one skilled in the art that other transparent conducting materials such as Zinc Oxide, Tin Oxide, Indium Tin Oxide, Indium Zinc Oxide can be used in the above embodiments. It will be understood to any one skilled in the art that the photosensitive nanoparticles can have various shapes—dots, rods, bipods, multipods, wires etc. It will be understood to any one skilled in the art that other conducting nanotube materials can be used in place of carbon nanotubes, TiO₂ nanotubes and ZnO nanotubes described in the embodiments. It will be understood to any one skilled in the art that other heat curable or radiation curable precursors can be used in place of the pentacene precursors. It will be understood to any one skilled in the art that other conducting polymers can be used in place PVK, P3HT and PEDOT. It will be understood to any one skilled in the art that a mixture of conducting and non-conducting polymer can be used in place of conducting polymers PVK, P3HT and PEDOT described in the embodiments.

The foregoing descriptions of specific embodiments and best mode of the present invention have been presented for purposes of illustration and description only. They are not intended to be exhaustive or to limit the invention to the precise forms disclosed. Specific features of the invention are shown in some drawings and not in others, for purposes of convenience only, and any feature may be combined with other features in accordance with the invention. Steps of the described processes may be reordered or combined, and other steps may be included. The embodiments were chosen and described in order to best explain the principles of the invention and its practical application, to thereby enable others skilled in the art to best utilize the invention and various embodiments with various modifications as are suited to the particular use contemplated. Further variations of the invention will be apparent to one skilled in the art in light of this disclosure and such variations are intended to fall within the scope of the appended claims and their equivalents. The publications referenced above are incorporated herein by reference in their entireties.

What is claimed is:

1. A photovoltaic device, comprising:
first and a second electrodes, at least one of which is a transparent electrode that is substantially transparent to all or part of the solar spectrum, and
a photoactive layer disposed between said first and second electrodes, where said photoactive layer comprises a first sublayer comprising first photoactive nanoparticles having a first band gap and a second sublayer comprising second photoactive nanoparticles having a second bandgap which is smaller than said first bandgap, where said first sublayer is disposed closer to said transparent electrode than said second sublayer.

2. The photovoltaic device of claim 1 wherein
(a) said first photoactive nanoparticles comprise nanoparticles that have a different size as compared to the size of said second photoactive nanoparticles, or
(b) said first and said second photoactive nanoparticles are ternary compositions that differ from each other in the amount of at least one atomic element present in said first and second photoactive nanoparticles,
wherein said photoactive nanoparticles are chosen to produce said first and said second bandgaps.

3. The photovoltaic device of claim 1 wherein at least one of said first or second sublayers comprises a mixture of (i) photoactive nanoparticles of the same size and (ii) photoactive nanoparticles having different composition, wherein the nanoparticles in said mixture have substantial the same band gap.

4. The photovoltaic device of claim 1 further comprising a second photoactive layer.

5. The photovoltaic device of claim 4 wherein said second photoactive layer comprises a first sublayer comprising first photoactive nanoparticles having a first band gap and a second sublayer comprising second photoactive nanoparticles having a second bandgap which is smaller than said first bandgap, where said first sublayer is disposed closer to said transparent electrode than said second sublayer, and wherein said first and second band gaps in said second photoactive layer are different from the first and second bandgaps of said first photoactive layer.

6. The photovoltaic device of claims 4 or 5 further comprising a recombination layer positioned between said first and said second photoactive layers.

7. The photovoltaic device of claim 4 or 5 further comprising a third photoactive layer.

8. The photovoltaic device of claim 7 wherein said third photoactive layer comprises a first sublayer comprising first photoactive nanoparticles having a first band gap and a second sublayer comprising second photoactive nanoparticles having a second bandgap which is smaller than said first bandgap, where said first sublayer is disposed closer to said transparent electrode than said second sublayer, and wherein said first and second band gaps in said third photoactive layer are different from the first and second bandgaps of said first and said second photoactive layers.

9. The photovoltaic devise of claim 1 wherein said first photoactive layer adsorbs UV, visible or infrared solar radiation.

10. The photovoltaic device of 4 or 5 wherein the first photoactive layer adsorbs UV, visible or infrared solar radiation and said second photoactive layer adsorbs one of the other of UV, visible or infrared solar radiation.

11. The photovoltaic device of claim 7 or 8 wherein said first, second and third photoactive layers each adsorb one of UV, visible or infrared solar radiation.

12. The photovoltaic device of claim 1, 5 or 8 wherein at least one of the sublayers in said first, second or third photoactive layers comprises a nanocomposite comprising said photoactive nanoparticles and an organic material that is hole or electron conducting.
